(19) United States
(12) Patent Application Publication
(10) Pub. No.: US 2025/0056164 A1
(43) Pub. Date: Feb. 13, 2025

(54) PIEZOELECTRIC MEMS CONTACT DETECTION SYSTEM

(71) Applicant: QUALCOMM Technologies, Inc., San Diego, CA (US)

(72) Inventor: Robert John LITTRELL, Belmont, MA (US)

(21) Appl. No.: 18/718,427

(22) PCT Filed: Mar. 2, 2023
(86) PCT No.: PCT/US2023/063616

§ 371 Date: Jun. 10, 2024

Related U.S. Application Data
(60) Provisional application No. 63/315,569, filed on Mar. 2, 2022.

(51) Int. Cl. H04R 17/00

(52) U.S. Cl. CPC H04R 17/00; H04R 2201/003

(57) ABSTRACT

Systems, devices, methods, and implementations related to contact detection are described herein. In one aspect, a system is provided. The system includes a first piezoelectric microelectromechanical systems (MEMS) transducer coupled to configured to generate a first analog signal when the first analog signal is transduced from vibrations propagating through the object. The system includes a second piezoelectric MEMS transducer having configured to generate a second analog signal transduced from acoustic vibrations at a location of the object, and classification circuitry coupled to the output of first piezoelectric MEMS transducer and the output of the second piezoelectric MEMS transducer, where the classification circuitry is configured to process data from the first analog signal and data from the second analog signal, and to categorize combinations of the first analog signal and the second analog signal received during one or more time frames.

### CROSS-REFERENCE TO RELATED APPLICATIONS

This application for patent is a 371 of international Patent Application PCT/US2023/063616, filed Mar. 2, 2023, which claims benefit of U.S. Provisional Application 63/315,569, filed Mar. 2, 2022, all of which are hereby incorporated by reference in their entirety and for all purposes.

### TECHNICAL FIELD

This disclosure relates generally to piezoelectric acoustic transducers, and more specifically to piezoelectric microelectromechanical systems (MEMS) vibration sensing devices that detect vibrations associated with an object surface.

### BACKGROUND

MEMS technology has enabled the development of smaller microphones and other acoustic transducers using wafer deposition techniques. In general, MEMS microphones can take various forms including, for example, capacitive microphones and piezoelectric microphones. MEMS capacitive microphones and electric condenser microphones (ECMs) currently dominate the consumer electronics microphone market. Piezoelectric MEMS systems such as microphones, however, are a growing market and offer various advantages. For example, piezoelectric MEMS microphones may not require a backplate which eliminates squeeze film damping (an intrinsic noise source for capacitive MEMS microphones). In addition, piezoelectric MEMS microphones are reflow-compatible and can be mounted to a printed circuit board (PCB) using lead-free solder processing, which could irreparably damage other types of microphones. These advantages, and others, may be more fully realized by improved piezoelectric MEMS microphones.

### SUMMARY

Various implementations of systems, methods, and devices within the scope of the appended claims each have several aspects, no single one of which is solely responsible for the desirable attributes described herein. Without limiting the scope of the appended claims, some prominent features are described herein. Aspects described herein include devices, wireless communication apparatuses, circuits, and modules supporting piezoelectric MEMS transducers.

One aspect is a system. The system comprises a first piezoelectric microelectromechanical systems (MEMS) transducer having a first output, where the first piezoelectric MEMS transducer is mechanically coupled to a surface of an object, and where the first piezoelectric MEMS transducer is configured to generate a first analog signal at the first output when the first analog signal is transduced by the first piezoelectric MEMS transducer from vibrations propagating through the object; a second piezoelectric MEMS transducer having a second output, where the second piezoelectric MEMS transducer is configured to generate a second analog signal at the second output when the second analog signal is transduced by the second piezoelectric MEMS transducer from acoustic vibrations at a location of the object; and classification circuitry coupled to the output of first piezoelectric MEMS transducer and the output of the second piezoelectric MEMS transducer, where the classification circuitry is configured to process data from the first analog signal and data from the second analog signal, and to categorize combinations of the first analog signal and the second analog signal received during one or more time frames.

Some such aspects are configured where the first piezoelectric MEMS transducer has a noise floor defining a noise at a given frequency related to a signal output in gravitational units (g), and where the noise floor is between 100 millionths of the gravitation unit (ug) per square root of frequency in Hertz (ug/sqrt (Hz)) and 0.5 ug/sqrt (Hz). Some such aspects are configured where the first piezoelectric MEMS transducer has a transduction bandwidth to detect the vibrations propagating through the object at frequencies between 1 kilohertz (kHz) and 8 kHz.

Some such aspects are configured where the data from the first analog signal comprises: frequency data for the vibrations propagating through the object; and magnitude data for the vibrations propagating through the object, where the magnitude data is associated with a severity of a contact with the object. Some such aspects are configured where the one or more time frames comprise a plurality of 20 millisecond (ms) frames.

Some such aspects are configured where the ASIC comprises an analog-to-digital converter (ADC), a digital signal processor (DSP), and a controller; where the output of the first piezoelectric MEMS transducer is coupled to an input of the ADC via a wire bond; where an output of the ADC is coupled to an input of the controller via the digital signal processor; and where an output of the controller is coupled to the classification circuitry.

Some such aspects are configured where the classification circuitry is further configured to detect a position of an impact on the surface of the object based on a time delay or a magnitude difference between vibrations detected at the first sensor package and vibrations detected at the second sensor package.

Some such aspects are configured where the classification circuitry is coupled to the output of the first piezoelectric MEMS transducer and the output of the second piezoelectric MEMS transducer via an application specific integrated circuit (ASIC), where the ASIC is configured to generate the data from the first analog signal and the second analog signal by: converting the first analog signal into a first plurality of data frames associated with the one or more time frames; converting the second analog signal into a second plurality of data frames associated with the one or more time frames; calculating a sum of a square of amplitude values for each data frame of the first plurality of data frames to generate an amplitude value for the first piezoelectric MEMS transducer for each of the one or more time frames; calculating a sum of a square of amplitude values for each data frame of the second plurality of data frames to generate and an amplitude value for the second piezoelectric MEMS transducer for each of the one or more time frames; and calculating a number of zero crossing for each data frame of the first plurality of data frames to generate a zero crossing value for the first piezoelectric MEMS transducer for each of the one or more time frames; calculating a number of zero crossing for each data frame of the second plurality of data frames to generate a zero crossing value for the second piezoelectric MEMS transducer for each of the one or more time frames; and calculating a ratio value for each of the one or more time frames, where the ratio value is a ratio between: the sum of the square of the amplitude for each data frame of the first plurality of data frames; and the sum of the square of the amplitude for each data frame of the second plurality of data frames.

Some such aspects are configured where the classification circuitry is further configured to receive the data from the first analog signal and the data from the second analog signal as training data in a training mode, and to match the data from the first analog signal and the data from the second analog signal to a provided training classification value.

Another aspect is a method for contact detection. The method includes storing, in a memory of a device, data from a first analog signal generated by a first piezoelectric microelectromechanical systems (MEMS) transducer having a first output, where the first piezoelectric MEMS transducer is mechanically coupled to a first surface of an object, and where the first piezoelectric MEMS transducer is configured to generate the first analog signal at the first output when the first analog signal is transduced by the first piezoelectric MEMS transducer from vibrations propagating through the object; storing, in the memory of the device, data from a second piezoelectric MEMS transducer having a second output, where the second piezoelectric MEMS transducer is configured to generate the second analog signal at the second output when the second analog signal is transduced by the second piezoelectric MEMS transducer from acoustic vibrations incident on the first surface of the object; and processing, using classification circuitry coupled to the output of first piezoelectric MEMS transducer and the output second piezoelectric MEMS transducer, the data from the first analog signal and the data from the second analog signal to categorize combinations of the first analog signal and the second analog signal received during one or more time frames.

Another aspect is a system for contact detection. The system includes means for generating a first analog signal transduced from vibrations propagating through an object having a first surface; means for generating a second analog signal transduced from acoustic signals incident on the first surface of the object; and means for processing data from the first analog signal and data from the second analog signal to classify combinations of the first analog signal and the second analog signal received during one or more time frames. Some such aspects are configured where the means for generating the first analog signal has a noise floor defining a noise at a given frequency related to a signal output in gravitational units (g), and where the noise floor is between 100 millionths of the gravitation unit (ug) per square root of frequency in Hertz (ug/sqrt (Hz)) and 0.5 ug/sqrt (Hz).

Another aspect is a system for contact detection. The system includes a motion sensor; a microphone; a machine learning engine; and at least one package containing the motion sensor, the microphone and the machine learning engine, the at least one package having a base to secure the motion sensor and microphone to a surface, the machine learning engine configured to be trained to differentiate different types of contact on the surface.

Some such aspects are configured where the base has solder pads that connect the at least one package to a printed circuit board that is in a housing, the housing being coupled with the surface. Some such aspects are configured where the motion sensor, the microphone and the machine learning engine are in a single package. Some such aspects are configured where the motion sensor and the microphone are in a first package and the machine learning engine is within a second package and electrically coupled with the first package. Some such aspects are configured where the motion sensor and the microphone are on a first die and the machine learning engine is on a second die, the first and second dies being within the single package. Some such aspects are configured where the motion sensor, the microphone, and the machine learning engine are formed on a single die. Some such aspects are configured where the microphone comprises a piezoelectric MEMS microphone. Some such aspects are configured where the motion sensor comprises an accelerometer or a piezoelectric MEMS microphone with an occluded aperture.

The foregoing, together with other features and embodiments, will become more apparent upon referring to the following specification, claims, and accompanying drawings.

### BRIEF DESCRIPTION OF DRAWINGS

FIG. 1 illustrates an example of an acoustic transducer system for contact detection and classification in accordance with aspects described herein.

FIG. 2A illustrates aspects of a piezoelectric microelectromechanical system (MEMS) sensor system in accordance with aspects described herein.

FIG. 2B illustrates aspects of a piezoelectric MEMS sensor device in accordance with aspects described herein.

FIG. 2C illustrates aspects of a piezoelectric MEMS sensor device in accordance with aspects described herein.

FIG. 3 illustrates aspects of a piezoelectric MEMS sensor device in accordance with aspects described herein.

FIG. 4 illustrates a cross-sectional view of one portion of a piezoelectric MEMS beam that can be used in accordance with aspects described herein.

FIG. 5 illustrates aspects of a system including a piezoelectric MEMS transducer in accordance with aspects described herein.

FIG. 6 illustrates aspects of a system including a piezoelectric MEMS transducer in accordance with aspects described herein.

FIG. 7 illustrates a method associated with contact detection and classification using MEMS transducers in accordance with aspects described herein.

FIG. 8A illustrates a method associated with contact detection and classification using MEMS transducers in accordance with aspects described herein.

FIG. 8B illustrates aspects of contact detection and classification using MEMS transducers in accordance with aspects described herein.

FIG. 8C illustrates aspects of contact detection and classification using MEMS transducers in accordance with aspects described herein.

FIG. 9 illustrates a method associated with contact detection and classification using MEMS transducers in accordance with aspects described herein.

FIG. 10A illustrates aspects of contact detection and classification using MEMS transducers in accordance with aspects described herein.

FIG. 10B illustrates aspects of contact detection and classification using MEMS transducers in accordance with aspects described herein.

FIG. 10C illustrates aspects of contact detection and classification using MEMS transducers in accordance with aspects described herein.

FIG. 10D illustrates aspects of contact detection and classification using MEMS transducers in accordance with aspects described herein.

FIG. 11 is a functional block diagram of an piezoelectric MEMS contact detection and classification system in accordance with aspects described herein.

FIG. 12 is a block diagram of a computing device that can be used with implementations of a piezoelectric MEMS contact detection and classification system in accordance with aspects described herein.

Like reference symbols in the various drawings indicate like elements.

### DETAILED DESCRIPTION

The detailed description set forth below in connection with the appended drawings is intended as a description of example aspects and implementations and is not intended to represent the only implementations in which the invention may be practiced. The detailed description includes specific details for the purpose of providing a thorough understanding of the example aspects and implementations. In some instances, some devices are shown in block diagram form. Drawing elements that are common among the following figures may be identified using the same reference numerals.

Aspects described herein include contact detection and classification systems using piezoelectric microelectromechanical systems (MEMS) transducers. Such transducers convert motion energy into electrical signals. An example of a MEMS transducer is a MEMS microphone, which converts sound pressure into an electrical voltage. Another example of a MEMS transducer is a motion detector, which converts movement into an electrical voltage. The size and low-power associated with such MEMS transducers can allow the MEMS transducers to be used in environments where other such sensors are unavailable. Aspects described herein include systems that detect vibrations associated with the surface of an object in order to detect and classify surface contacts associated with the detected vibrations.

Some aspects include a combination of an piezoelectric MEMS acoustic detector and a piezoelectric MEMS motion detector coupled to a surface of an object to detect motion (e.g., mechanical vibrations) and sound (e.g., acoustic vibrations) incident on the surface. The data derived from electrical signals output by the MEMS detectors can, in some aspects, be processed by a classifier or machine learning engine to generate additional system operations associated with a given type of signal. For example, a system can include data patterns that match surface contacts associated with a collision or with a key scratching paint on a surface of the object. In some aspects, such data patterns can be generated by a machine learning system connected to a surface of an object, and recording the data generated by particular actions (e.g., key scratching on a car door, collisions with a car bumper, etc.) The data can be used to train a classifier, neural network, or other such machine learning engine. Devices can then be created with sensors with a same placement in a similar object used for the data generation (e.g., mass manufactured car doors). Electrical connections from the sensors in the object to control and processing circuitry can be used to generate alerts or actions based on classifications of sensed vibrations.

In some aspects, multiple piezoelectric MEMS transducers of the same type (e.g., multiple microphones and multiple motion detectors) can be placed in different positions on a surface. Time differences and other variations in signals detected at each MEMS transducer can be used to determine where on a surface of an object a contact originates (e.g., based on a time delay, amplitude variations, or other differences between electrical signals produced from a same contact).

In some aspects, a contact sensing system is configured to differentiate and/or characterize different types of contact on a surface. To that end, some aspects include a motion detector and microphone that combine with a machine learning engine to produce the desired results. In some aspects, the motion detector has a low noise floor, a high bandwidth (e.g., a wide band of detected vibration frequencies), or both. In some aspects, these elements are formed on a shared die. In other aspects, the elements are formed on separate dies. Details of various illustrative aspects are discussed further below.

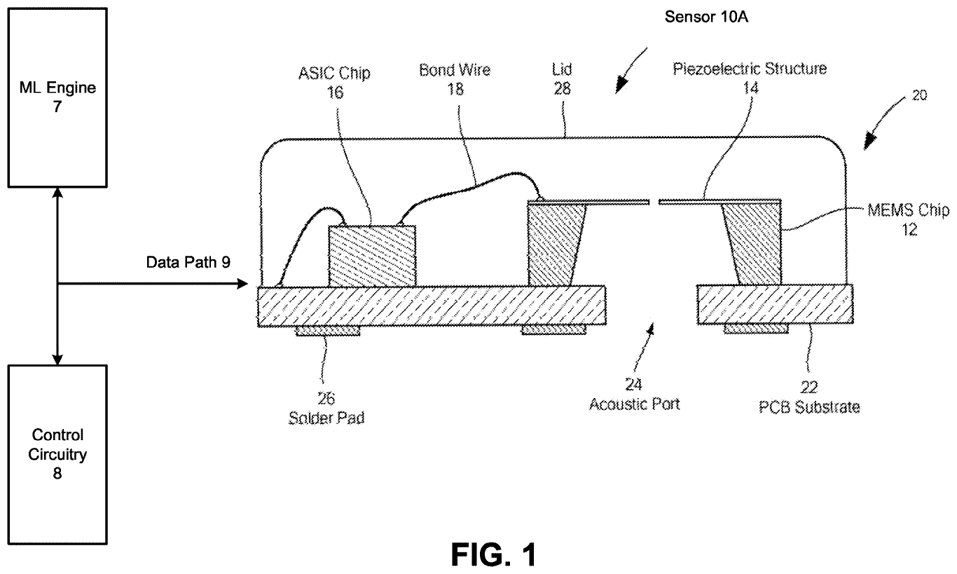

FIG. 1 illustrates an example of a system for contact detection and classification using MEMS transducers in accordance with aspects described herein. FIG. 1 schematically shows a cross-sectional view of an acoustic sensor 10A. As shown, the sensor 10A of FIG. 1 includes a MEMS chip 12 which can include a die having piezoelectric structures 14, (e.g. cantilevered beams or diaphragms, to convert vibrational energy into electrical signals), and an application-specific integrated circuit (ASIC) chip 16 to buffer and amplify the electrical signal generated by the MEMS chip 12. The MEMS chip 12 and ASIC chip and 16 are electrically connected by wire bonding 18, and mounted within the interior chamber of a package (although other packaging and connection techniques are possible). The package has a lid 28 and a substrate 22 (e.g., a printed circuit board). The PCB Substrate 22 and the MEMS substrate of the MEMS chip 12 form an acoustic port 24 for enabling sound pressure to access the piezoelectric structure(s) 14 of the MEMS chip 12 Multiple solder pads 26 are disposed on a bottom surface of the PCB substrate 22 for solder connections of the MEMS transducer 10 as an element of additional devices. The MEMS transducer of the MEMS chip 12 can, for example, be used as a microphone or other sensor in cell phones, laptop computers, portable microphones, smart home accessories, or any other such devices. A lid 28 can be used to form the housing of the MEMS chip 12, to provide an air pocket which provides one side of the air pressure differentiation that causes deflection and signal generation in the MEMS chip 12, and to mitigate electromagnetic interference (EMI). As indicated above, in some aspects, the sensor 10 can be implemented without the acoustic port 24 to implement an accelerometer, where the piezoelectric structure 14 will generate an electrical signal based on motion of the MEMS transducer 10, rather than based on an incident acoustic (e.g., ultrasonic) signal from the acoustic port 24.

FIG. 1 illustrates a structure with the MEMS chip 12 having an acoustic port 24 formed in the MEMS substrate. In other implementations, the MEMS substrate can be closed, with a pocket similar to the pocket formed by a cavity below the piezoelectric structures 14 and the acoustic port 24 on the opposite side of the piezoelectric structure(s) 14 from the substrate 22. In other implementations, other such configurations of the acoustic port 24 can be used so long as a path for acoustic pressure to reach the piezoelectric structures 14 is present.

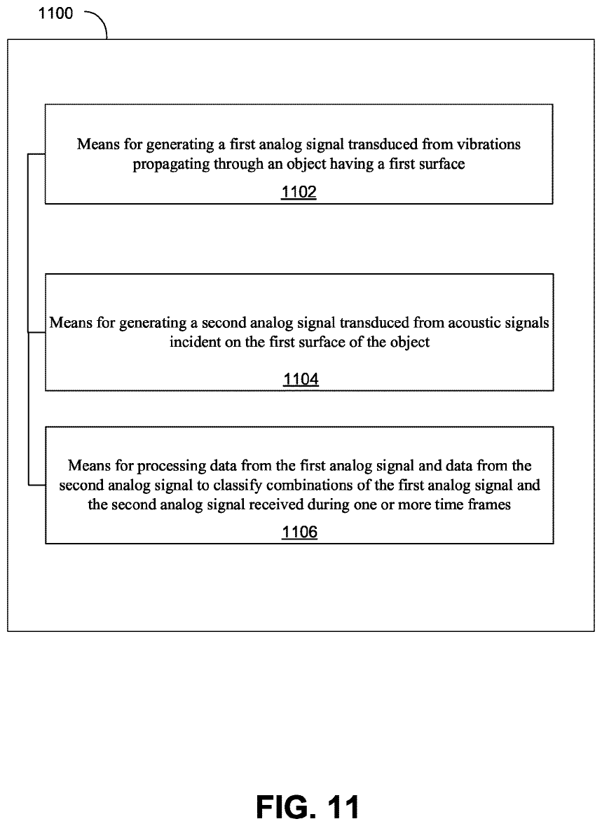

FIG. 1 additionally illustrates a machine learning engine 7 and control circuitry 8 coupled to the ASIC chip 16 via a data path 9. In some aspects, the machine learning engine 7 can be a neural network or classification circuitry separate from additional processing circuitry of a system such as control circuitry 8. In some aspects, the machine learning engine 7 can include decision tree circuitry, support vector machine circuitry, a convolutional neural network circuitry, or other such classification or contact detection and characterization circuitry. In some aspects, the control circuitry 8 and the machine learning engine 7 can be implemented using one or more processors of a device using shared resources in a computing architecture as illustrated by FIG. 11, with the control circuitry and machine learning engine implemented by a processor 1210 and the sensor 10A acting as an input device 945. The machine learning engine 7 can process signals output from the ASIC chip 16 (e.g., generated from analog signals provided by the MEMS chip 12) to determine a type of motion being detected by the MEMS chip 12. The classification or type determination performed by the machine learning engine can generate an output provided to the control circuitry 8. The control circuitry 8 can then perform selected actions based on the classification information provided by the machine learning engine 7.

In some aspects, rather than implement the system with two separate chips, some embodiments may implement both the MEMS chip 12 and ASIC 16 as part of the same die. Accordingly, discussion of separate chips is for illustrative purposes. In addition, in other embodiments the ASIC 16 may be implemented on a die in a separate package with one or more interconnects electrically coupling the MEMS chip 12 to the ASIC 16. Similarly, the amplifier discussed above and used for feedback transduction in a feedback transduction loop can, in some aspects, be implemented on an ASIC 16 separate from the MEMS chip 12. In other aspects, the amplifier can be implemented as part of a combined IC with both MEMS and ASIC components of the MEMS chip 12 and the ASIC 16.

Further, as illustrated below, a sensor can be implemented with multiple piezoelectric MEMS transducers either on a single MEMS chip, or on separate MEMS chips.

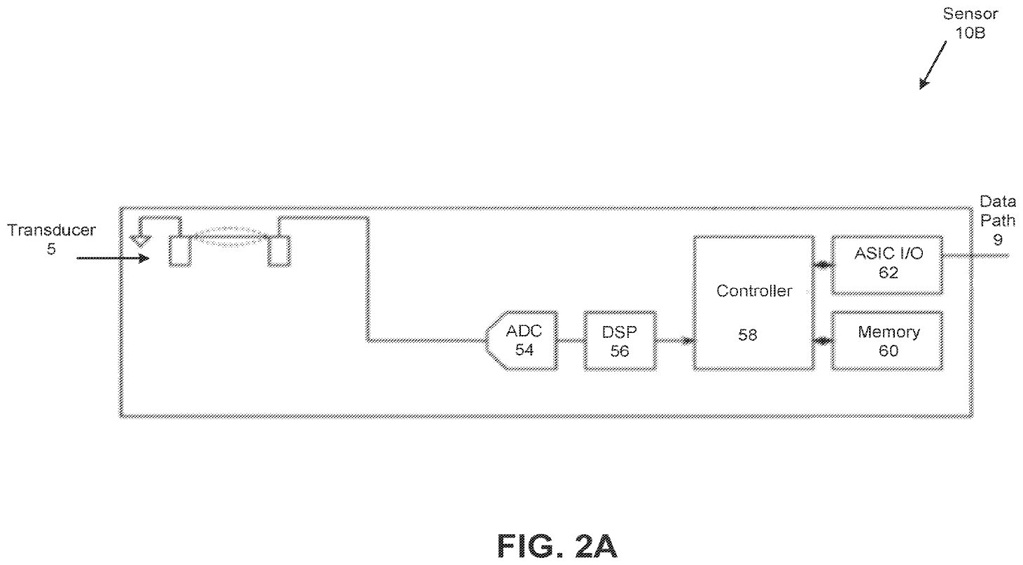

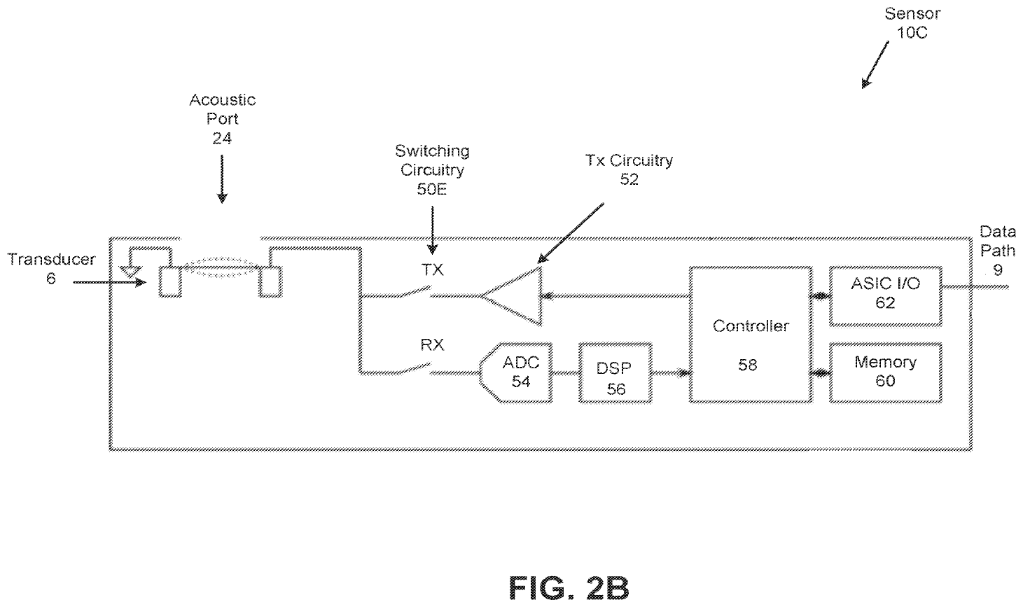

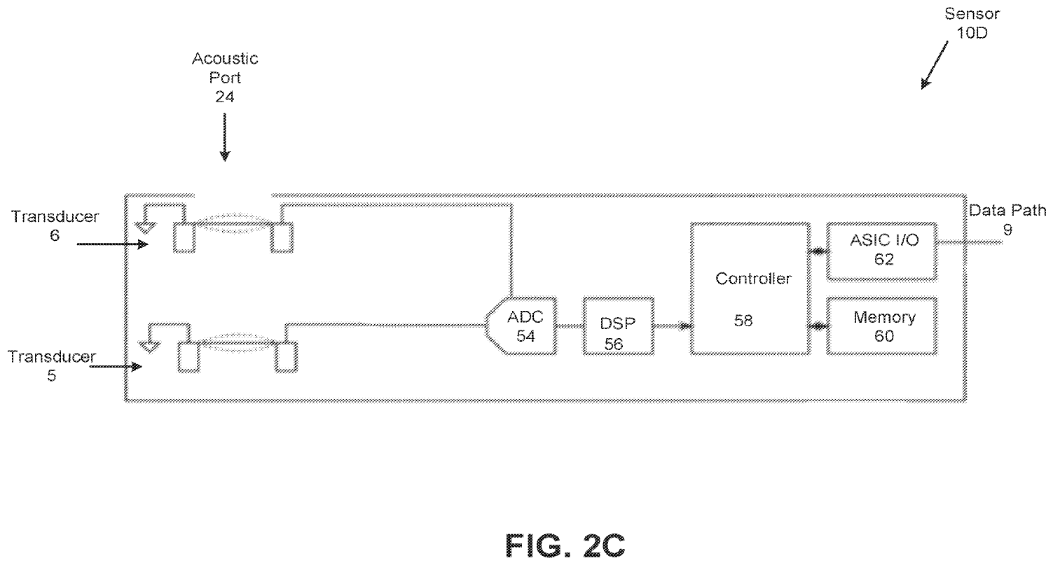

FIG. 2A illustrates aspects of a piezoelectric microelectromechanical system (MEMS) sensor 10B in accordance with aspects described herein. As illustrated, the sensor 10B includes a piezoelectric MEMS transducer 5. The piezoelectric MEMS transducer can be implemented on a MEMS chip such as the MEMS chip 12 of FIG. 1. An output of the transducer 5 is coupled to an analog-to-digital converter (ADC) 54, which accepts an analog signal from the output of the transducer 5 and converts the analog signal (e.g., which is a transduced signal from motion vibrations detected at the piezoelectric MEMS transducer 5) to a digital signal. An output of the ADC 54 is provided to a digital signal processor (DSP) 56, which can perform preprocessing, digital filtering, or other signal conditioning on the information from the transducer 5, and provide an output signal to a controller 58. The controller 58 can further process the information from the transducer 5 to generate a digital data signal corresponding to the analog signal output from the transducer 5. The digital data signal can be stored in a memory 60 on the sensor 10B, or can be output to a the data path 9 via application specific integrated circuit (ASIC) input/output (I/O) circuitry 62.

As illustrated, the transducer 5 does not have an associated acoustic port 24. In some aspects, a similar MEMS chip 12 described in FIG. 1 can be used for the transducer 5 operating as a motion detector, but with the associated sensor not having the acoustic port 24. In such an implementation, the PCB substrate 22 substrate can be closed without the cap of acoustic port.

FIG. 2B illustrates details of a MEMS transducer 10C in accordance with aspects described herein. As illustrated, a transducer can include a transducer 6 having an acoustic port 24. In addition, in contrast to the implementation of FIG. 2A with a motion detector transducer 5 configured only to receive vibrational signals, the transducer 6 in the sensor 10C can transmit signals in addition to receiving signals. The sensor 10C can allow acoustic waves to be transmitted out from the transducer 6 in a transmit mode, or to be sensed in a receive mode. Switching circuitry 50 allows controller 58 to select between receive (Rx) and transmit (Tx) operation. In a Tx mode, an electrical signal associated with an acoustic wave to be generated by the transducer 6 is received as an input at the ASIC input/output (I/O) 62, and passed to controller 58. The signal (e.g., as modified by the controller 58 to shape this signal for the transducer 6) may be stored in memory 60 for later use, or passed to Tx circuitry 52 for transmission. The Tx circuitry 52, as part of transmission operations, can perform additional waveform conditioning and amplification (e.g., via a power amplifier), before being sent to the transducer 6 to be converted to acoustic signals.

In a receive mode, the MEMS chip 12 receives incident acoustic waves via the acoustic port 24, which are converted to electrical signals by the transducer 6. Just as with the motion sensor transducer 5 described above, the ADC 54 and the DSP 56 convert the analog electrical signal from the MEMS chip 12 to a format acceptable to the controller 58, which can either store the signal in memory 60 or transmit the signal to additional processing circuitry of a larger device via the ASIC I/O 62.

As described herein, aspects can include transducer signals for both acoustic (e.g., microphone) and mechanical (e.g., motion sensor) vibrations used to detect and classify contacts with a surface. In some aspects, separate sensors 10 can be used for acoustic and motional detection. Such aspects can include separate packages co-located on a surface of an object to generate analog signals and corresponding data associated with a similar location on a surface of an object. In other aspects, a shared package can be used for multiple transducers (e.g., on a shared PCB substrate such as the PCB substrate 22 with the same lid such as the lid 28).

FIG. 2C illustrates aspects of a piezoelectric MEMS sensor 10D in accordance with aspects described herein. The sensor 10D includes two transducers, shown as the transducer 6 and the transducer 5. The transducer 6 can be a microphone receiving acoustic signals via the acoustic port 24, and the transducer 5 can be a motion detector without exposure to an acoustic port as described above. In some aspects, the transducers 5 and 6 can be implemented on a single MEMS chip such as the MEMS chip 12. In other aspects, multiple different MEMS chips can be used. For example, in one aspect, two MEMS chips can be positioned on a shared substrate under a shared lid, similar to the illustration of FIG. 1, but with a second MEMS chip in addition to the MEMS chip 1. Such aspects can also include multiple ASICs, or can use a single ASIC to process analog signals from multiple transducers. FIG. 2C illustrates the sensor 10D with two transducers 6 and 5. Other aspects can include additional transducers, such as transducers for different frequency ranges (e.g., two or more microphones detecting different acoustic frequency ranges or two or more motion sensors detecting different ranges of mechanical vibration frequencies).

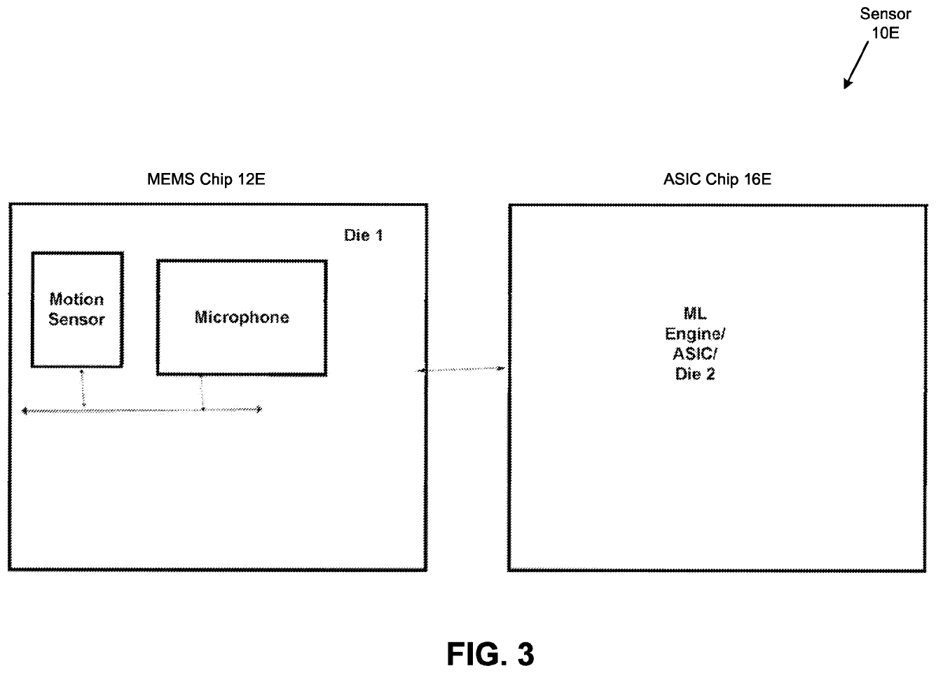

FIG. 3 illustrates aspects of a piezoelectric MEMS sensor 10E in accordance with aspects described herein. FIG. 3 schematically shows more details of the sensors described above. The sensor 10E illustrates an implementation with a single MEMS chip 12E (e.g., which can be an implementation of the MEMS chip 12 of FIG. 1) that includes a first die having a motion sensor (e.g., a first piezoelectric mems transducer such as the transducer 5) configured to detect motion, a microphone configured to detect acoustics (e.g., a second piezoelectric mems transducer such as the transducer 6), and a second die implementing a machine learning engine in a separate ASIC chip 16E. The ASIC chip 16E is configured to use the data from the microphone and motion detector to determine information about the contact (e.g., an impact on a surface of an object containing or attached to the sensor 10E). The sensor 10E can be implemented in a package having a base (e.g., the PCB substrate 22) to which all three of these components are mounted. As such, the motion sensor should detect motion of the surface to which it is secured. Alternative embodiments, however, may use two or more packages to form the single sensor (e.g., on a printed circuit board). For example, the motion sensor and microphone may be in a first package while the machine learning engine implemented using the ASIC chip 16E may be in a second package. Other embodiments may divide all three elements into three different packages. As described herein, the MEMS chip 12E can be a shared MEMS die (e.g., the MEMS chip 12 with a microphone and a motion detector mounted on the PCB substrate 22 configured as a package substrate). Such a configuration with two sensors on the same die and a machine learning engine (e.g., the ML engine 7) integrated onto an ASIC chip (e.g., the ASIC chip 16) provides for a device with an improved compact form factor compared to a device with each component configured in separate discrete chips (e.g., two separate MEMS sensors, a separate ASIC, and a separate ML IC).

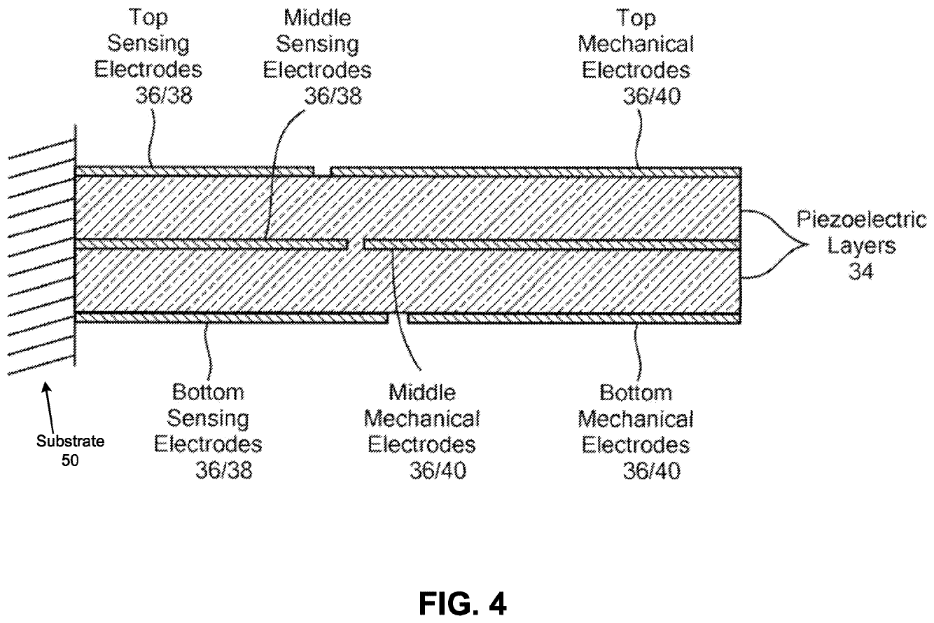

FIG. 4 illustrates a cross-sectional view of one portion of a MEMS microphone in accordance with aspects described herein. FIG. 4 shows an example cross-sectional view of one of those cantilevers 30. Other aspects of a piezoelectric MEMS acoustic transducer may use more or fewer cantilevers 30. Accordingly, as with other features, discussion of eight cantilevers 30 is for illustrative purposes only. These triangular cantilevers 30 are fixed to a substrate 50 (e.g., a silicon substrate) at their respective bases and are configured to freely move in response to incoming/incident sound pressure (i.e., an acoustic wave). The intersection of the substrate 50 and the piezoelectric layers (e.g., as well as the electrodes at the substrate 50) are the fixed end of the cantilever(s) 30. Triangular cantilevers 30 can provide a benefit over rectangular cantilevers as the triangular cantilevers can be more simply configured to form a gap controlling geometry separating an acoustic port (e.g., the acoustic port 24) on one side of the cantilevers of the piezoelectric MEMS acoustic transducer from an air pocket on the other side of the cantilevers. Specifically, when the cantilevers 30 bend up or down due to either sound pressure or residual stress, the gaps between adjacent cantilevers 30 typically remain relatively small and uniform in the example symmetrical shapes with fixed ends using the triangular cantilevers 30.

The electrodes 36 are generally identified by reference number 36. However, the electrodes used to sense signal are referred to as “sensing electrodes” and are identified by reference number 38. These electrodes are electrically connected in series to achieve the desired capacitance and sensitivity values. In addition to the sensing electrodes 38, the rest of the cantilever 30 also may be covered by metal to maintain certain mechanical strength of the structure. However, these “mechanical electrodes 40” do not contribute to the electrical signal of the microphone output. As discussed above, some aspects can include cantilevers 30 without mechanical electrodes 40.

As described above, as a cantilever 30 bends or flexes around the fixed end, the sensing electrodes 36/38 generate an electrical signal. The electrical signal from an upward flex (e.g., relative to the illustrated positioning in FIG. 3, will be inverted compared with the signal of a downward flex. In some implementations, the signal from each cantilever 30 of a piezoelectric MEMS acoustic transducer can be connected to the same signal path so that the electrical signals from each cantilever 30 are combined (e.g., a shared bond pads 48). In other aspects, each cantilever 30 may have a separate signal path, allowing the signal from each cantilever 30 to be processed separately. In some aspects, groups of cantilevers 30 can be connected in different combinations. In some aspects, switching circuitry or groups of switches can be used to reconfigure the connections between multiple cantilevers 30 to provide different characteristics for different operating modes, such as transmit and receive modes.

In one aspect, adjacent cantilevers 30 can be connected to separate electrical paths, such that every other cantilever 30 has a shared path. The electrical connections in such a configuration can be flipped to create a differential signal. Such an aspect can operate such that when an acoustic signal incident on a piezoelectric MEMS acoustic transducer causes all the cantilevers 30 to flex upward, half of the cantilevers 30 create a positive signal, and half the cantilevers 30 create a negative signal. The two separate signals can then be connected to opposite inverting and non-inverting ends of an amplifier of an analog front end. Similarly, when the same acoustic vibration causes the cantilevers 30 to flex downward, the signals of the two groups will flip polarity, providing for a differential electrical signal from the piezoelectric MEMS acoustic transducer.

Alternatively, rather than alternating cantilevers 30 within a single piezoelectric MEMS transducer to create a differential signal, identical MEMS transducers can be placed across a shared acoustic port (e.g., the acoustic port 24), with the connections to the amplifier of an analog front-end reversed and coupled to different inverting and non-inverting inputs of a differential amplifier of the analog front-end to create the differential signal using multiple piezoelectric MEMS transducers.

The cantilever 30 can be fabricated by one or multiple layers of piezoelectric material sandwiched by top and bottom metal electrodes 36. FIG. 3 schematically shows an example of this structure. The piezoelectric layers 34 can be made by piezoelectric materials used in MEMS devices, such as one or more of aluminum nitride (AlN), aluminum scandium nitride (AlScN), zinc oxide (ZnO), and lead zirconate titanate (PZT). The electrodes 36 can be made by metal materials used in MEMS devices, such as one or more of molybdenum (Mo), platinum (Pi), nickel (Ni) and aluminum (Al). Alternatively, the electrodes 36 can be formed from a non-metal, such as doped polysilicon. These electrodes 36 can cover only a portion of the cantilever 30, e.g., from the base to about one third of the cantilever 30, as these areas generate electrical energy more efficiently within the piezoelectric layer 34 than the areas near the central end (e.g., the free movement end) of each cantilever 30. Specifically, high stress concentration in these areas near the base induced by the incoming sound pressure is converted into electrical signal by direct piezoelectric effect.

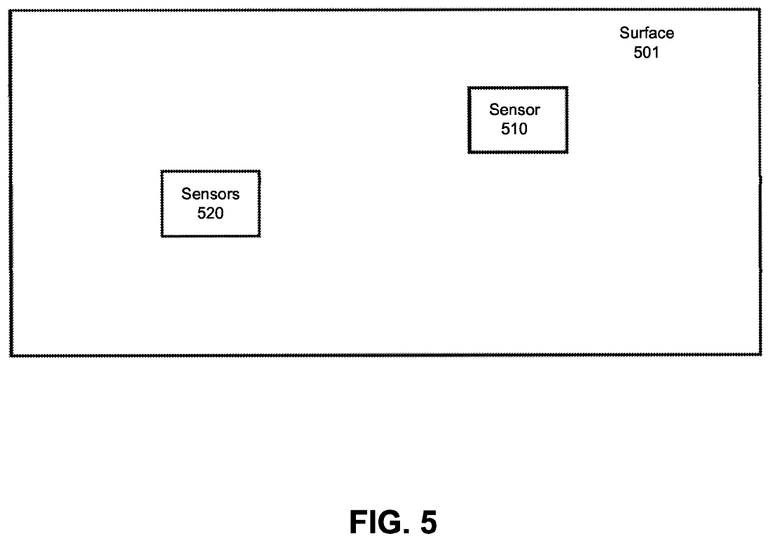

FIG. 5 illustrates aspects of a system including a piezoelectric MEMS transducer in accordance with aspects described herein. FIG. 5 schematically shows a surface 501 with a plurality of sensors configured in accordance with illustrative embodiments. By way of example, the surface 501 may be the panel of a car, such as a car door or fender. As shown, the surface 501 has sensor 510 and sensor 520 mounted to it. In some aspects, the surface 501 having sensors 510, 520 mounted on the surface 501 can be an interior surface to protect the sensors. In other aspects, the sensors can be mounted on externally facing surfaces of an object to improve response times and quality of vibration signals received at sensors, with externally facing sensors configured to be replaced following damaging contacts, and systems using multiple sensors to identify when a collision may damage externally facing sensors. In other aspects, the sensors can be in any position on a surface of an object where vibrations are transmitted to the sensors. In some aspects, a single sensor can be used, or more than two sensors can be used. The sensors 510, 520 can be any of the sensors 10A-E illustrated above, or any similar sensors.

The sensors 510, 520 can include internal controls or closely connected controls (e.g., managed by a controller such as the controller 58 to allow operation in a lower power mode until vibrations having a threshold energy value are detected. When the vibrational energy detected at one or more of the plurality of sensors exceeds the threshold energy value, the controller can shift to an operating mode in a configuration to detect a contact with the surface 501. The sensors can then generate output data for classification circuitry that can be used to determine whether a type of contact is associated with one or more actions to be taken by control circuitry (e.g., the control circuitry 8 or a processor 1210). The classification circuitry, for example, can differentiate among types of contact and/or make other determinations related to the contact. Such determinations can relate to a severity or magnitude of a contact with an object or the surface 501 of the object (e.g., a hard or soft contact) and whether the contact damaged the surface 501 or another surface of the object (e.g., such as a scratch or dent on a car panel).

As indicated above, the each of the plurality of sensors 510, 520, and additional sensors can include multiple transducers to generate data used by classification circuitry to make such determinations. In some aspects, each of the plurality of sensors includes a first piezoelectric MEMS transducer and a second piezoelectric MEMS transducer (e.g., similar to any transducer described above or a transducer with a piezoelectric beam as described in FIG. 3 or any similar piezoelectric beam for electromechanical signal transduction). The first piezoelectric microelectromechanical systems (MEMS) transducer has a first output, where the first piezoelectric MEMS transducer is mechanically coupled to a surface of an object having the surface 501 and/or additional surfaces, and where the first piezoelectric MEMS transducer is configured to generate a first analog signal at the first output when the first analog signal is transduced by the first piezoelectric MEMS transducer from vibrations propagating through the object. Similarly, the second piezoelectric MEMS transducer has a second output, where the second piezoelectric MEMS transducer is configured to generate a second analog signal at the second output when the second analog signal is transduced by the second piezoelectric MEMS transducer from acoustic vibrations incident on the surface of the object. Classification circuitry coupled to the output of first piezoelectric MEMS transducer and the output of the second piezoelectric MEMS transducer operates to process data from the first analog signal and data from the second analog signal (e.g., as modified from the analog signals by an ADC, a DAC, a controller, etc.). The classification circuitry can operate using various thresholds or categorization mechanisms to generate an output categorizing combinations of the first analog signal and the second analog signal received during one or more time frames.

As illustrated in FIG. 5 the sensor 510 and the sensor 520 are each positioned in different locations. The sensor 510 is positioned at a first position on the surface 501 of the object and the sensor 520 is positioned at a second position on the surface of the object at a predetermined distance from the first position. Sensors 510, 520 and any additional sensors present on an object may cooperate to determine a location and/or a direction the direction of contact. For example, if a key is dragged across a car door, the sensors may be configured to recognize the contact, duration, velocity, location, magnitude, and/or direction of the key/door contact. In this manner, various embodiments may be considered to have formed a touch surface, analogous to a touch screen, which has that functionality. As noted above, however, some embodiments may have no more than a single sensor on a surface. Such an embodiment therefore may not provide the functionality of the embodiments with two or more sensors on a single surface. In some aspects, the classification circuitry is configured to detect a position of an impact on the surface of the object based on a time delay or a magnitude difference between vibrations detected by different sensors such as the sensors 510 and the sensor 520 based on the known positions of the sensors 510, 520.

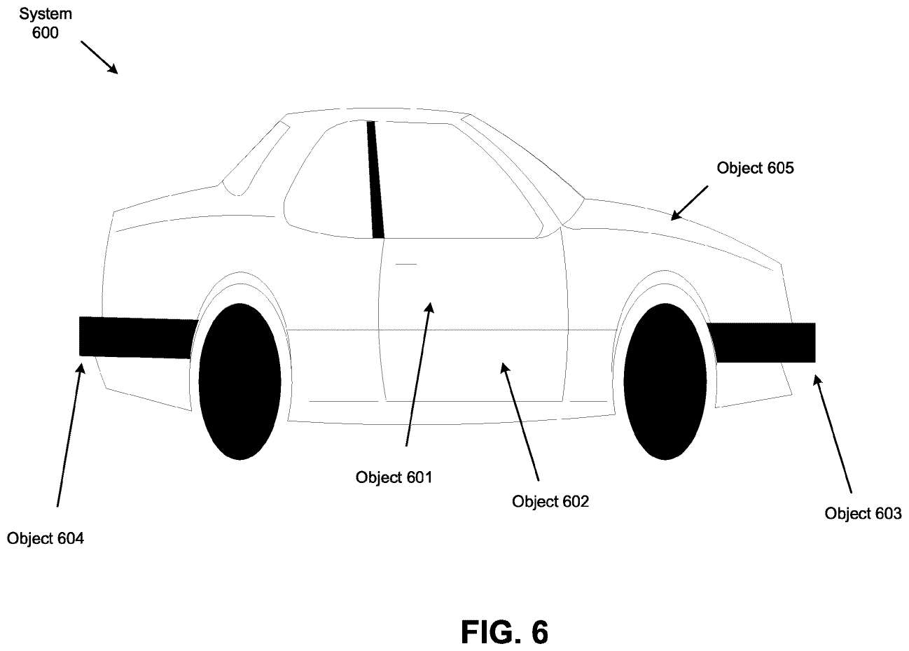

FIG. 6 illustrates aspects of a system 600 including a piezoelectric MEMS transducer in accordance with aspects described herein. The system 600 is a car including a plurality of objects that make up the car. FIG. 6 illustrates a plurality of different objects 601, 602, 603, 604, and 605 that partially make the car of the system 600. The object 601 is an upper car door panel, the object 602 is a lower car door panel, the object 603 and the object 604 are ach bumpers, and the object 605 is a hood panel. Each of the objects 601 through 605 can be solid panels or objects that have consistent mechanical characteristics related to the transmission of mechanical or acoustic vibrations through the object. For any of the objects 601 through 605, a collision or impact on an outward facing surface generates both acoustic and mechanical vibrations on an interior surface of the object where sensors can be mounted, such as the surface 501 of FIG. 5.

Additionally, while multiple sensors, such as sensors 510, 520 in a single panel on a surface 501 can have similar signals due to the sensors being mounted on a same surface of a panel, sensors mounted in different objects such as the object 601 and the object 602 can also provide data to classification circuitry that can be used in classifying data. For example, sensors such as the sensor 10D of FIG. 2C can have high sensitivity and can detect, for example, vibrations from the closing of another car door near the object 602 where no physical contact occurs with the object 602. Similarly, if sensors in the object 602 and the object 601 detect similar acoustic vibrations, but much stronger mechanical or motion vibrations are detected by sensors in the object 601, data from transducer signals can be used by classification circuitry to analyze a possible impact on an exterior surface of the object 601. If the object 602 has multiple sensors, the sensors can assist in providing an estimated location of an impact on the object 601, or on another object not containing a sensor, such as a glass window above the door panel of the object 601. Similarly, sensors in the bumper objects 604 and 603 can provide data to assist in classification of an impact on either bumper.

A testing mode of a system such as the system of FIG. 1 can be used with the system 600 to generate machine learning data that can be used by a classification system to identify patterns of data to associate with control system alerts (e.g., automatically generated alerts managed by the control circuitry 8) and patterns of signals to differentiate from important classifiers. For example, in a training mode, sensors of the system 600 (e.g., attached to surfaces of the objects 601 through 606) can record data. The data can be matched to known events or past context types associated with training data, which can be used to train machine learning circuitry (e.g., the machine learning engine 7). Such data and matched known events can, for example, be bumper collisions, car doors hitting a panel or other object of the system 600 and creating a paint scratch, rain incident on the system 600, or a key scratch. After training of the classification circuitry (e.g., the machine learning engine 7), an operating mode can be used to detect signals that match the known events from the training. Control circuitry can then be configured to take actions when known events associated with actions occur. For example, when a data matching an adjacent car door hitting an object of the system 600 occurs, a camera can be activated to capture images of the object and any damage or paint scratch occurs, and to capture details of the adjacent car that caused the impact or an area surrounding the impact. Similarly, data matching a key scratch can be used to initiate video capture and/or do send a wireless communication signal to a mobile device associated with the system 600. Data associated with a balloon popping, by contrast, can be identified as a non-contact event or an event with no associated action to be initiated by a system.

In a system such as the system 600 of FIG. 6, each sensor can provide data to a central system or computing device similar to the computing device of FIG. 11. Such a central computing device can accept the data as generated from transducer analog signals (e.g., using ADC, DAC, and controller circuitry in a sensor package), process aggregated sensor data to determine if a contact occurred, and to classify the contact and perform any control system actions dictated for a given contact type.

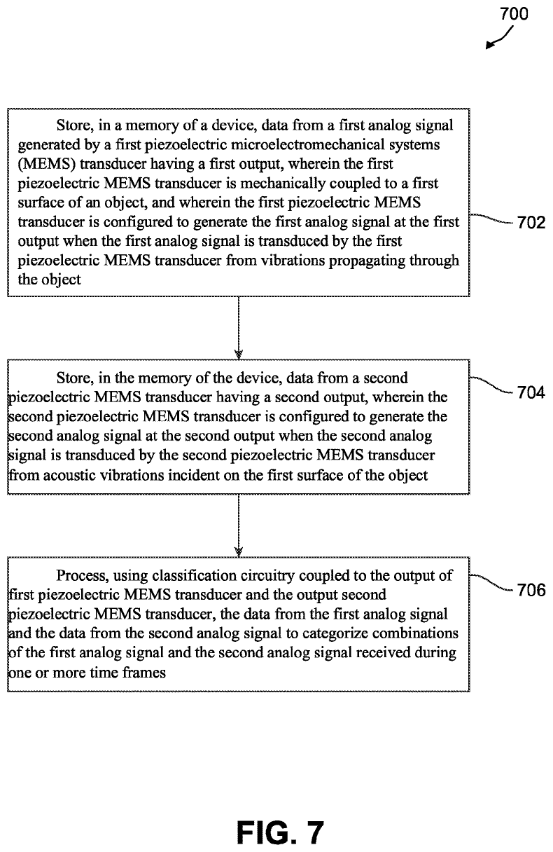

Training data generated using the system 600 can be provided with copies of the system 600 so that similar systems have access to a memory storing known similar information. For example, an automotive manufacturer may have the training data and provide access to that data and include a system for generating and updating training data from users. The data can be produced using a representative sample of the specific sensor itself (e.g., a sample of the sensor system, which includes the motion sensor and microphone). Other embodiments may use the sensor being trained to produce known contacts and recording the response of the system. In either case, those responses are stored and used by classification circuitry and/or an associated machine learning engine. As discussed below, those responses produce a plurality of motion data hallmarks (sometimes referred to herein as “motion data” or “representative data characteristics”) that are correlated to specific contact or event types (e.g., as detailed further below in FIGS. 7, 8, and 9).

Additionally, while automotive applications are discussed, various embodiments may apply to other applications. For example, the surface 501 may be a surface of an object such as an element of a robots, a storage containers, walls of buildings, hulls of ships, airplane panels, etc. Any such system can include one or more sensors in accordance with aspects described herein. The sensor or sensors in any such system can include a package containing a motion sensor configured to detect motion, a microphone configured to detect acoustics, and a machine learning engine configured to use the data from the microphone and motion detector to determine information about the contact. The package has a base to which all three of these components are mounted. As such, the motion sensor should detect motion of the surface to which it is secured. Alternative embodiments, however, may use two or more packages to form the single sensor (e.g., on a printed circuit board). For example, the motion sensor and microphone may be in a first package while the machine learning engine may be in a second package. Other embodiments may divide all three elements into different packages.

In some aspects, the sensors can be configured as low power wake-up, high bandwidth, and/or low noise floor sensors. A low noise floor of piezoelectric MEMS transducers allows collection of significant amounts of data, but risks false alerts automatically being generated at excessive rates without contact signal thresholds and classification circuitry to limit excess signaling that can occur if user alerts or notifications are generate for all sensor signals above a noise floor. In some aspects, piezoelectric MEMS transducers of sensors (e.g., the sensors 510, 520) have a noise floor of approximately 100 micrograms (ug) per square root of vibration frequency (sqrt (Hz)) (ug/sqrt (Hz)). Other sensors can have a noise floor of approximately 0.5 ug/sqrt (Hz) at 1 KHz, 50 ug/sqrt (Hz) to 5 ug/sqrt (Hz) at 1 KHz. In some aspects, different transducers for acoustic and mechanical vibration sensing can have different characteristics. (e.g., a motion sensor may have a noise floor of between 100 ug/sqrt (Hz) and 0.05 ug/sqrt (Hz) at device resonance and/or 5 ug/sqrt (Hz) to 0.05 ug/sqrt (Hz) at resonance with an acoustic sensor having a different noise floor). In addition, in some aspects a sensor can have a detection bandwidth for vibrations between 1 Kilohertz and 8 Kilohertz. In other examples, other frequency ranges can be used, with less data for a ML algorithm as bandwidth is reduced, and more ML processing resources needed for additional ML data as bandwidth is increased. In some aspects, a sensors can be configured to operate with an overall sensor power usage of 20 Microwatts or less during a low-power pre-wake up mode. Different implementation environments can use different sensor designs in accordance with aspects described herein. Here, the noise floor has units of acceleration given in standard gravitational units (g), where one g is 1× the earth's gravitational acceleration (1 g=˜9.8 m/s2). The difference with prior transducers is that prior systems may have been around 300 millionths of a g per square root of a cycle (ug/sqrt (Hz) at 1 KHz and examples described herein can operate at about 13 ug/sqrt (Hz). Within a narrow band around resonance, our noise floor is below 1 ug/sqrt (Hz).

Further, while different aspects are described in the context of different packaging configurations, it will be apparent that a wide variety of integrated packaging of multiple or single transducers and supporting circuitry can be used in different applications. For example, while some aspects above show motion detectors, acoustic detection microphone, and a machine learning engine in a single die integrated package, other aspects can operate with separate dies and packages for each of these objects.

As noted above, the machine learning engine determines the type of motion. Accordingly, illustrative embodiments train the machine learning engine to provide that functionality. To that end, FIGS. 7, 8, and 9 illustrate operations that can be used to generate either training data or operating data. Training data is matched with a known event to generate machine learning system associations between data patterns and events, and operating data is provided by sensors to classification circuitry during operation to allow the classification circuitry to indicate if the operating data is associated with a pattern identified by the machine learning engine during training. shows one process of training. Those skilled in the art may use other techniques for training the machine learning engine. This methods therefore should be considered examples simplified from longer processes that may be used to train the machine learning engine. Accordingly, the illustrated methods of FIGS. 7, 8, and 9 can be practices with additional, repeated, or intervening steps. Those skilled in the art therefore can modify the process as appropriate.

FIG. 7 illustrates a method associated with piezoelectric MEMS contact detection systems in devices in accordance with aspects described herein. FIG. 7 illustrates an example method 700 for operation of a transducer system (e.g., a system in accordance with any aspect described above). In some aspects, the method 700 is implemented by a transducer system, such as a system integrated with a device within a computing system or device (e.g., a computing system 1200) as described below. In some aspects, the method 700 is implemented as computer readable instructions in a storage medium that, when executed by processing circuitry of a device, cause the device to perform the operations of the method 700 described in the blocks below. The method 700 illustrates one example aspect in accordance with the details provided herein. It will be apparent that other methods, including methods with intervening or repeated operations, are possible in accordance with the aspects described herein.

The method 700 includes block 702, which describes storing, in a memory of a device, data from a first analog signal generated by a first piezoelectric microelectromechanical systems (MEMS) transducer having a first output, where the first piezoelectric MEMS transducer is mechanically coupled to a first surface of an object, and where the first piezoelectric MEMS transducer is configured to generate the first analog signal at the first output when the first analog signal is transduced by the first piezoelectric MEMS transducer from vibrations propagating through the object.

The method 700 additionally includes block 704, which describes storing, in the memory of the device, data from a second piezoelectric MEMS transducer having a second output, where the second piezoelectric MEMS transducer is configured to generate the second analog signal at the second output when the second analog signal is transduced by the second piezoelectric MEMS transducer from acoustic vibrations incident on the first surface of the object.

The method 700 additionally includes block 706, which describes processing, using classification circuitry coupled to the output of first piezoelectric MEMS transducer and the output second piezoelectric MEMS transducer, the data from the first analog signal and the data from the second analog signal to categorize combinations of the first analog signal and the second analog signal received during one or more time frames.

Additional, repeated, and intervening operations can be performed in addition to the operation of the method 700 to implement contact detection in accordance with any details provided herein.

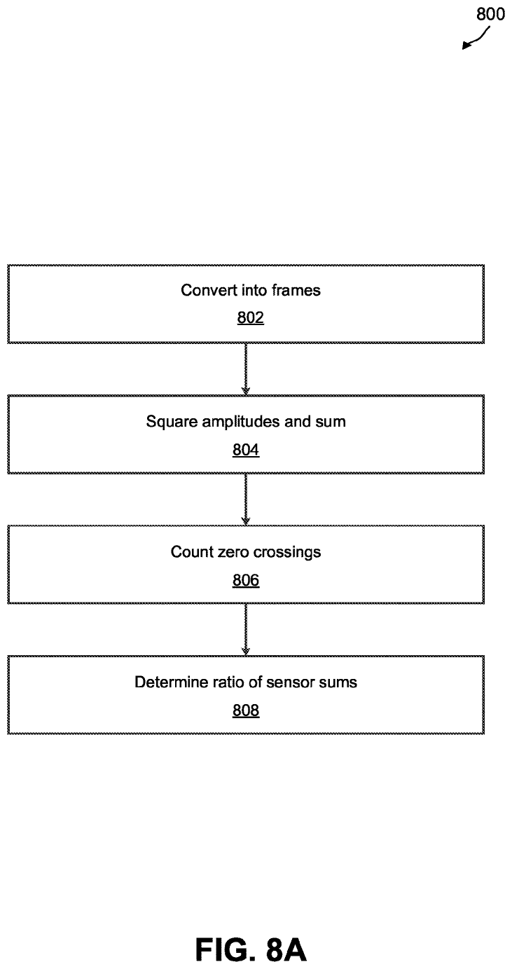

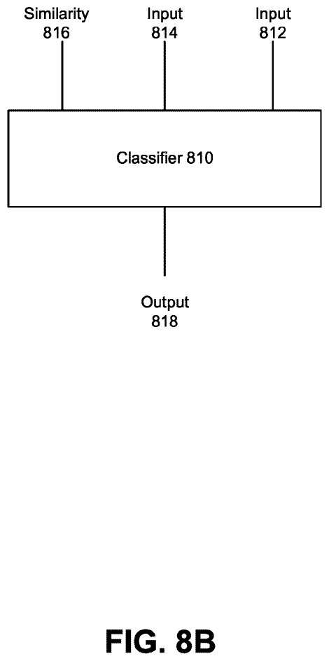

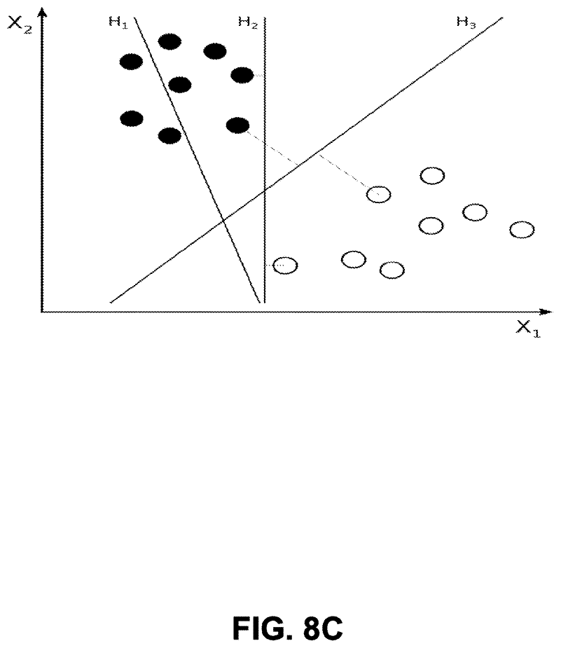

FIG. 8A illustrates another example method 800 in accordance with some aspects. The method 800 describes an alternative method for operation of a contact system in accordance with aspects described herein.

The method 800 includes block 802, which involves conversion of contact information into a plurality of frames for analysis. The size of the frames can be a function of the data and timing. In some aspects, each frame is twenty milliseconds (ms). The contact information for each frame may be in the form of a waveform that may or may not have one or more zero-crossings. Each frame then is processed by operations of the blocks 804, 806, and 808 to produce motion data hallmarks (e.g., characteristic data for each frame).

The method 800 includes block 804, where processing circuitry squares the amplitude(s) of the waveform of the frame to ensure the data has no negative values. These amplitudes may be in digital form, although in some aspects, analog mixing can be used to square analog signals from piezoelectric MEMS transducers of a sensor. After squaring the amplitudes, the block 804 further involves summing all the squared amplitudes produce a single amplitude value. A corresponding analog step can integrate the squared signal to generate the single analog value. The block 804 involves performing the same steps for each signal of each piezoelectric MEMS transducer of a sensor. In some aspects, such operations can be performed serially for data from a first piezoelectric MEMS sensor and a second piezoelectric MEMS sensor. In other aspects, operations of the block 804 are performed in parallel for signals from different transducers. In an application with two transducers (e.g., a microphone and a motion detector), the block 804 produces two data values. One single amplitude value is generated for each transducer (e.g., the microphone and the motion sensor.)

In a corresponding manner, block 806 involve processing circuitry calculating a number of zero-crossings for signals from each piezoelectric MEMS transducer. As with block 804, this step also produces two data values one zero-crossing number for each piezoelectric MEMS transducer. The zero crossing value reflects a primary frequency content of energy detected by a given transducer. If the frequency of the frame signal is higher, then there be a correspondingly higher number of zero crossings (e.g., within a detection bandwidth of a given transducer).

The block 808 then involves operations to determine a ratio of the number of sums of squared amplitudes (e.g., values from the block 804) for different transducers. In an implementation with a microphone (e.g., an acoustic transducer) and a motion sensor, the block 808 produces a ratio of signals associated with acoustic and mechanical vibrations. Such a ratio can allow a characterization system to distinguish between loud noise or high amplitude acoustic vibrations (e.g., which may not be in an audible frequency range) not associated with an object contact, and high amplitude vibrations (e.g., which may or may not be in an audible frequency range) associated with a contact (e.g., a collision). In aspects with more than two transducer signals, the system design can determine which ratios are most relevant to classifying an incident or contact associated with matching (e.g., same time period) data signals.

The method 800 results in five data points of data which characterize transducer data about the nature and scope of the specific contact associated with the frame. If a known training classifier is associated with the data, additional operations train the machine learning engine. During device operation (e.g., not a training mode), such data can be processed by a machine learning engine to classify any match with trained incidents or contact types. For example, a system can be trained to identify a specific number of contact types (e.g., 8, 16, 32, etc.). In some examples, contacts not matching a trained data pattern can be processed by control circuitry according to additional rules, such as an amplitude or energy threshold.

A trained sensor can match the trained contact types to the data that consists of the five illustrated data points per frame, and perform additional operations according to rules in control systems.

FIG. 8B illustrates a generalized classifier 810. In some aspects, the classifier 810 can be used to implement the method 800 of FIG. 8A. In other aspects, other implementations or methods can be implemented using the classifier 810. The classifier 810 has an input 812 and an input 814. In some aspects, the input 812 can be a motion sensor input configured to accept analog motion sensor data from a MEMS sensor as described above, or digital data processed from a MEMS sensor (e.g., using a DSP and/or ADC as described above in FIG. 1). In such aspects, the input 814 can be an audio sensor input configured to accept an analog signal or digital data generated from a MEMS acoustic sensor. Similarity 816 input can be used to provide settings, an operating mode, or other control input for the classifier 810. For example, the similarity 816 input can be used, in some aspects, for managing training data inputs or providing a classification for training data provided at the inputs 812, 814 during a training mode. During an operating mode (e.g., as opposed to a training mode or a low power sleep mode), the classifier 810 can receive data via the inputs 812, 814 and any additional data via similarity 816, and provide a contact classification value at the output 818 (e.g., a noise contact, a key scrape contact, a minor car collision contact, a major car collision contact, etc.)

Such inputs can be associated with multiple sensors, such as in a car or other device having any number of sensors or combinations of sensors (e.g., pairs of motion and audio sensors). For example, there may be two microphones to perform audio analysis on a contact type. The microphones may detect if the location of the sound source is external to the car (e.g., audible), or also made contact with the door (e.g., scratch, bump, soft contact, hard contact, etc.). That is, the location is on the door or not on the door, and further may be differentiated by loudness and/or level of contact on the door. In addition, for each microphone and motion sensor pair, may result in one classification type. There may be multiple classifiers, one classifier per motion sensor and microphone pair. The output of the multiple classifiers may be combined. For example, if both classifiers indicate a contact type that provides a higher confidence in the contact type result. If both classifiers do not indicate the same contact type, a separate classification would have to be repeated until the contact types matched. This may happen, for example, because there is not enough memory or buffer to store a history of past frames or contact types.

FIG. 8C then illustrates aspects of operation of the classifier 810 in accordance with some implementations. In FIG. 8C, the x-axis X1 can represent the data from the input 812, and the y-axis can represent the data from the input 814. Lines H1, H2, and H3 can represent classification thresholds or similarity 816 inputs used to identify different classification groupings. The various data points can be data combinations from the sensors in a given time period, and the output 818 can provide data on where groupings of data fall within the classification thresholds or a classification output associated with data groupings within the classification thresholds as indicated. In some aspects, the classifier 810 can take a motion signal at the input 812 and a microphone signal at 814, and generate a classification signal at the output 818 based on the classification grouping generated by analysis of the data compared with the H1, H2, and H3 classification thresholds.

As described herein, in some aspects, the machine learning engine (e.g., the machine learning engine 7) can be a support vector machine or support vector network. In machine learning, support vector machines (SVMs) are supervised learning models with associated learning algorithms that analyze data for classification and regression analysis. SVMs are a robust prediction method, being based on statistical learning frameworks or VC theory. Given a set of training examples, each marked as belonging to one of two categories, an SVM training algorithm builds a model that assigns new examples to one category or the other, making it a non-probabilistic binary linear classifier (e.g., methods such as Platt scaling exist to use SVM in a probabilistic classification setting). SVM maps training examples to points in space so as to maximize the width of the gap between the two categories. New examples are then mapped into that same space and predicted to belong to a category based on which side of the gap they fall.

In addition to performing linear classification, SVMs can efficiently perform a non-linear classification using what is called the kernel trick, implicitly mapping their inputs into high-dimensional feature spaces. When data are unlabeled, supervised learning is not possible, and an unsupervised learning approach is required, which attempts to find natural clustering of the data to groups, and then map new data to these formed groups. The support vector clustering algorithm, applies the statistics of support vectors, developed in the support vector machines algorithm, to categorize unlabeled data.

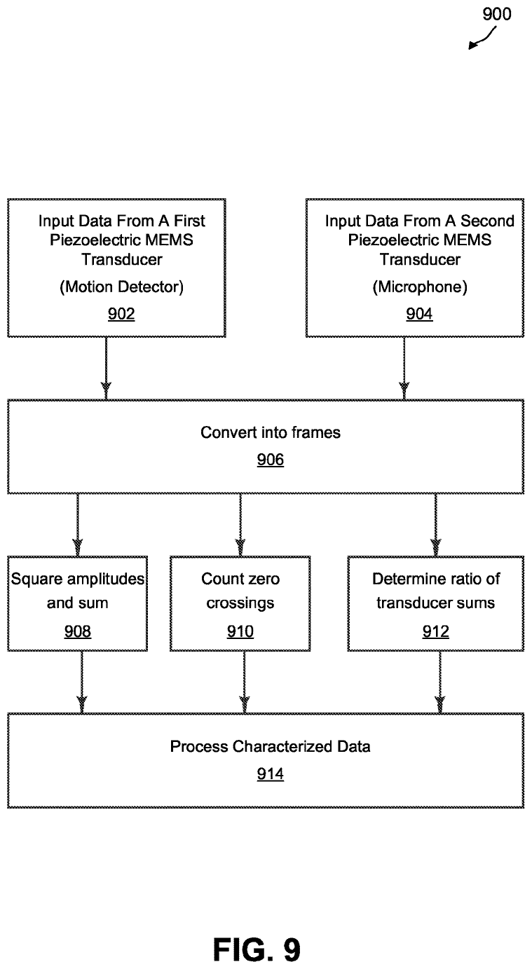

FIG. 9 illustrates another example method 900 in accordance with some aspects. The method 900 of FIG. 9 illustrates operations similar to the operations of FIG. 8A, with the operations for generating data from analog piezoelectric MEMS transducer signals performed in parallel.

Method 900 involves blocks 902 and 904 receiving parallel streams of input data from different piezoelectric MEMS transducer. In the example of the block 902, the data is from a motion detector transducer, and in the example of the block 904, the data is from a microphone. As described above, in some aspects, data streams as describe in the blocks 902 and 904 are only generated with a threshold detection occurs to wake sensors of a system from a low power mode. In other aspects, an “always on” operation can be used to gather transducer input data when the consumed power is low in comparison to the available power or a value in detecting initial vibration data.

Additionally, the method 900 illustrates collection of two parallel data streams from two transducers in the blocks 902 and 904. In other aspects, any number of data streams can be used. For example, in some aspects such as in the system 600 of FIG. 6, each object can have two transducers with data processed independently and then further analyzed after characterization of the two signals from each object (e.g., with the method 900 repeated for transducer data for each object of the system 600). In other aspects, sensors from each object can be jointly characterized (e.g., with input data similar to the blocks 902 and 904 jointly characterized in a method similar to the method 900).

The method 900 involves block 906, where data from the blocks 902 and 904 are converted into frame data. Such conversion can involve a clock timing with a start and an end time period identified for time frames, and each data stream from the block 902 and the block 904 segmented into data frames matching data collected for each corresponding time period of a time frame. In various aspects, a time period used for data frames can be matched to expected vibration frequency and time periods that generate accurate characterization data for the events to be characterized by the classification circuitry. For aspects involving car panels, 20 ms may be used. In other aspects, such as ship hulls or airplane panels with larger panel objects or where different vibrational frequencies may be present and key to contact characterization, different time frames can be used.

Blocks 908, 910, and 912 involve parallel processing of data in the same manner described above in corresponding block 804, 806, and 808 (e.g., with 804 corresponding to 908, 806 corresponding to 910, and 808 corresponding to 912). The characterized data can then either be stored and associated with a set of actions and a contact type during training (e.g., a collision, key scratch, etc.) or matched with training data in an operating mode to identify a contact by matching operating data with previously stored training data.

Block 914 then involves processing the data from the earlier blocks, either to format the blocks for a classifier or other machine learning engine, or processing by the machine learning engine.

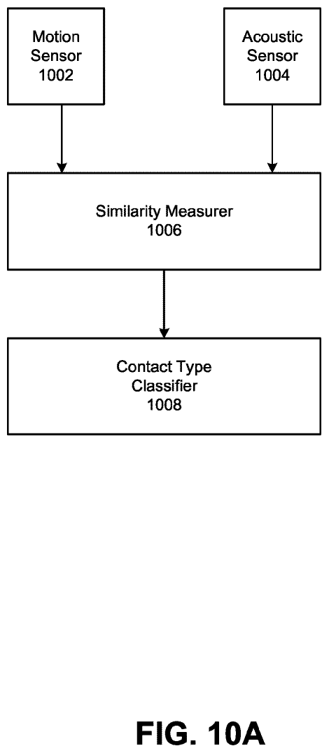

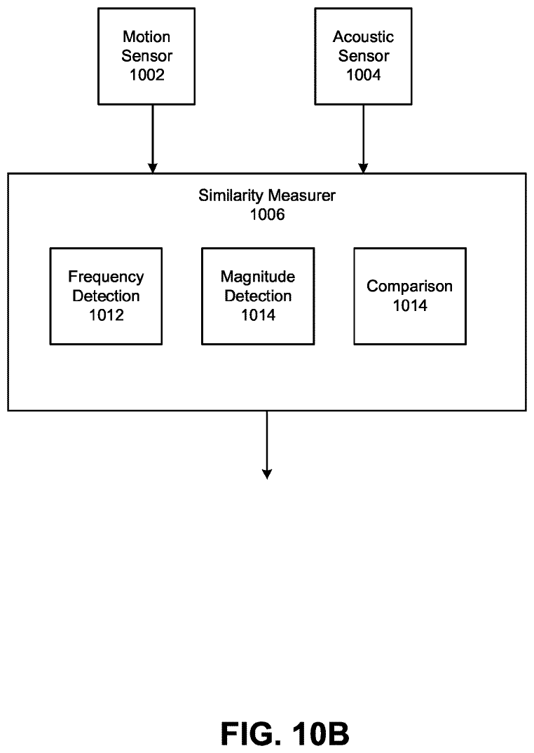

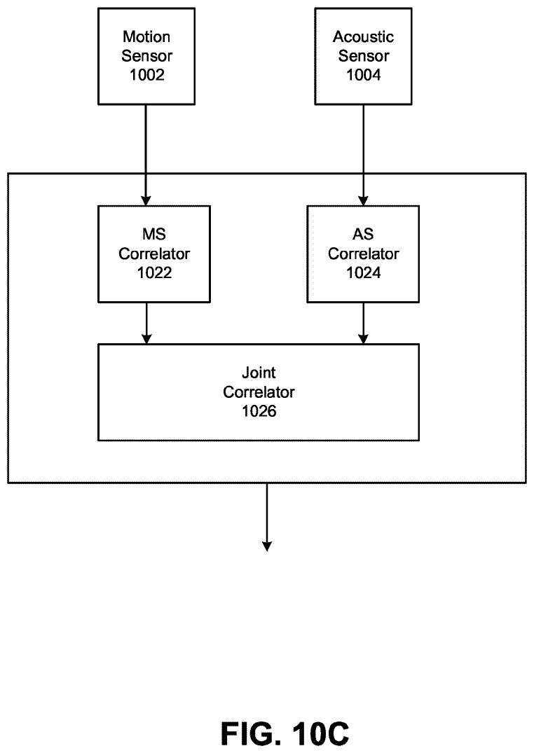

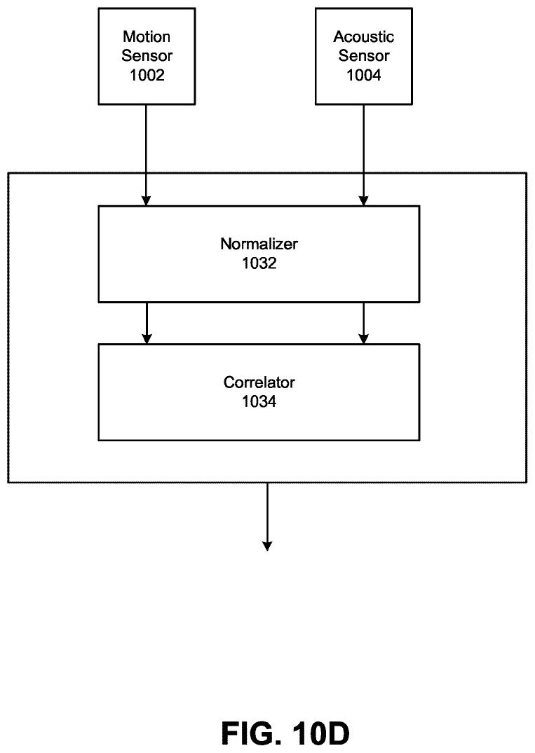

FIG. 10A-D illustrate aspects of contact detection and classification using MEMS transducers in accordance with aspects described herein. The illustrated systems of FIGS. 10A-10D can, for example, be used to implement the method 900 or any similar method described herein. The system of FIG. 10A, for example, includes two sensors, shown as motion sensor 1002, and acoustic sensor 1004. A similarity measurer 1006 can process the data signals and generate standardized data that can be used by a contact type classifier 1008 to generate a contact type output indicating information (e.g., location, type, severity, etc.) for a contact expected given the data from the sensors 1002, 1004. The combination of steps square amplitudes and sum 804, count zero crossings 806, and determine ratio of sensor sums 808 in FIG. 8A may also be represented generally as a similarity measure or, and may be incorporated as part of an alternative to other embodiments described herein. The combination of steps 802, 804 and 806 of FIG. 8A may be incorporated as part of the similarity measurer 1006 shown in FIG. 10A. The combination of steps square amplitudes 908, count zero crossings 910, and determine ratio of transducer sums 912 in FIG. 9 may also be represented generally as a similarity measure or, and may be incorporated as part of an alternative to other embodiments described herein. The combination of steps 908, 910 and 912 of FIG. 9 may be incorporated as part of the similarity measurer 1006 shown in FIG. 10A. In some aspects described herein, similar operations which normalize or standardize signals from MEMS sensors can be processed using circuitry that performs similarity operations which are not the exact operations described in FIGS. 8 and 9. Such operations can be operations to improve the performance, accuracy, and/or standard operation of classification or machine learning engine circuitry.

FIG. 10B illustrates an example of the system of FIG. 10A that can be matched to the method 900. The similarity measurer 1006 of FIG. 10B includes frequency detection 1012 that can perform frequency detection operations to quantify frequency characteristics of a signal, such as the operations of block 806 or block 910. Magnitude detection can perform operations to quantify amplitude characteristics of signals, such as the operations of block 804 or block 908. Comparison 1014 can perform operations such as those of block 808 or block 912.

FIGS. 10C and 10D illustrate additional examples of systems for processing sensor data. As illustrated, FIG. 10C includes the sensors 1002, 1004, with a correlation block 1022 for the motion sensor 1002, a correlation block 1024 for the acoustic sensor 1004, and a joint correlator 1026 for the sensor combination. In such an aspects, independent similarity operations can be used in addition to joint similarity operations to process sensor data and provide inputs to a classifier. FIG. 10D illustrates a normalizer 1032 for both sensors 1002, 1004, and a correlator 1034 that uses an output of the normalizer 1032. In other aspects, any number of data operations can be used. Such systems can support correlation operations between sensor data, autocorrelation operations for a data stream, absolute value calculations, rectification operations, and other such operations.

In the above aspects illustrated in FIGS. 10A-D, the similarity measurers can, for example, implement operations of the blocks 804, 806, and/or 808 of the method 800, the blocks 908, 910, and/or 912 of the method 900, or other such blocks and associated operations for generating data from MEMS sensors that can be input into a machine learning engine (e.g., a neural network, a decision tree, a support vector machine, etc.) to generate a decision or classification output in accordance with aspects described herein.

A first set of aspects includes:

Aspect 1. A device comprising: a memory configured to store an audio signal and a motion signal; one or more processors configured to: obtain the audio signal, wherein the audio signal is generated based on detection of sound by a microphone; obtain the motion signal, wherein the motion signal is generated based on detection of motion by a motion sensor mounted on a surface of an object; perform a similarity measure based on the audio signal and the motion signal; and determine a context of a contact type of the surface of the object based on the similarity measure.

Aspect 2. The device of Aspect 1, wherein the one or more processors are configured to perform the similarity measure based on a first comparison between a representation of the audio signal and a representation of the motion signal.

Aspect 3. The device of Aspect 2, wherein the first comparison is a difference of the representation of the audio signal and the representation of the motion signal.

Aspect 4. The device of Aspect 2, wherein the first comparison is a ratio of the representation of the audio signal and the representation of the motion signal.

Aspect 5. The device of Aspect 2, wherein the representation of the audio signal is a first correlation and the representation of the motion signal is a second correlation.

Aspect 6. The device of Aspect 2, wherein the representation of the audio signal is based on a rectification of the audio signal as obtained by the one or more processors.

Aspect 7. The device of Aspect 2, wherein the first comparison between the representation of the audio signal and the representation of the motion signal is based on: a second comparison of the representation of the audio signal to an audio threshold; and a third comparison of the representation of the motion signal to a motion threshold, 8. The device of any of Aspects 1 to 6, wherein to determine the context of the contact type of the surface of the object includes classifying the contact type based on a combination of the representation of the audio signal and the representation of the motion signal.

Aspect 8. The device of Aspect 2, wherein to determine the context of the contact type of the surface of the object includes classifying the contact type based on a combination of the representation of the audio signal and the representation of the motion signal.

Aspect 9. The device of any of Aspects 1 to 8, wherein to determine the context of the contact type of the surface of the object includes classifying the contact type based on a magnitude of contact.

Aspect 10. The device of any of Aspects 1 to 8, wherein the context of the contact type of the surface of the object includes at least one of: a scratch, a dent, touch, a non-contact touch, damage, hard touch.

Aspect 11. The device of any of Aspects 1 to 8, wherein to determine the context of the contact type of the surface of the object includes comparison of a machine learning engine output to past context types of contacts determined by a machine learning engine.

Aspect 12. The device of Aspect 11, wherein the machine learning engine is one of: a decision tree, support vector machine, or neural network.

Aspect 13. A device comprising: a memory configured to store an audio signal and a motion signal; and one or more processors configured to: obtain the audio signal based on detection of sound by a microphone; obtain the motion signal based on detection of motion by a motion sensor mounted on a surface of an object; quantify frequency characteristics of the audio signal and the motion signal; quantify amplitude characteristics of the audio signal and the motion signal; perform one or more comparisons of the audio signal and the motion signal to generate comparison data; and determine a context of a contact type of the surface of the object based on the frequency characteristics, the amplitude characteristics, and the comparison data.

Aspect 14. A device comprising: a memory configured to store an audio signal and a motion signal; and one or more processors configured to: obtain the audio signal based on detection of sound by a microphone; obtain the motion signal based on detection of motion by a motion sensor mounted on a surface of an object; generate digital correlation data for the audio signal; generate digital correlation data for the motion signal; generate joint correlation data for the audio signal and the motion signal; select a classification based on the joint correlation data.

Aspect 15. A device comprising: a memory configured to store an audio signal and a motion signal; and one or more processors configured to: obtain the audio signal based on detection of sound by a microphone; obtain the motion signal based on detection of motion by a motion sensor mounted on a surface of an object; normalize the audio signal and the motion signal to generate a normalized audio signal and a normalized motion signal; generate correlation data from the normalized audio signal and the normalized motion signal; and determine a contact classification using the correlation data.

Aspect 16. A device comprising: a memory configured to store an audio signal and a motion signal; and one or more processors configured to: obtain the audio signal based on detection of sound by two or more microphones; obtain the motion signal based on detection of motion by two or more motion sensor mounted on a surface of a first object; perform one or more comparisons of the audio signal and the motion signal to generate comparison data; determine a context of a contact type of the surface of the object based on the comparison data; and determine a location of a second object within a threshold distance to the first object based on the context determined by the one or more processors.

Aspect 17. The device of Aspect 16, wherein a plurality of cantilevered beams are configured as a membrane enclosing a sensor area.

Aspect 18. The device of any of Aspects 16 to 17 wherein the first object is a car door.

Aspect 19. The device of any of Aspects 16 to 18, wherein the second object is a person, a key, or a balloon.

Aspect 20. The device of any of Aspects 16 to 19, wherein the contact type includes a location of an area of the first object.

Aspect 21. The device of any of Aspects 16 to 17, wherein the first object is a door, and wherein the location of the area of the first object is one of: an upper right part of the door, a lower right part of the door, an upper left part of the door, a lower left part of the door, or center of the door

As described, such aspects can include various implementations of a contact detection system with circuitry to perform similarity measurements to facilitate classification or machine learning operations in accordance with aspects described herein. The illustrated aspects provide details of some possible implementations, and additional implementations will be apparent from the details provided herein, including aspects with additional or repeated elements, or alternate configurations to accomplish contact detections and associated actions in a device.

FIG. 11 is a functional block diagram of a wireless communication apparatus configured for contact detection in accordance with aspects described herein. The apparatus 1100 comprises means 1102 for means for generating a first analog signal transduced from vibrations propagating through an object having a first surface. The means 1102 can, for example, be the transducer 6 or a MEMS motion detector formed from the cantilevered beam of FIG. 3 or any other such MEMS sensor described herein.

The apparatus 1100 comprises means 1104 for generating a second analog signal transduced from acoustic signals incident on the first surface of the object. The means 1104 can, for example, be the transducer 5 or a MEMS motion detector formed from the cantilevered beam of FIG. 3 or any other such MEMS sensor described herein.

The apparatus 1100 comprises means 1106 for processing data from the first analog signal and data from the second analog signal to classify combinations of the first analog signal and the second analog signal received during one or more time frames. The means 1106 can include ML engine 7, or any other ML engine circuitry, such as circuitry for a neural network, a decision tree, and/or a support vector machine, In some aspects, the means 1106 can additionally include processing circuitry such as the ASIC chip 16, the control circuitry 8, the ADC 54, the DSP 56, the controller 58, or any other such circuitry used to generate and process data from the first and second analog signals generated by the means 1102 and the means 1104.

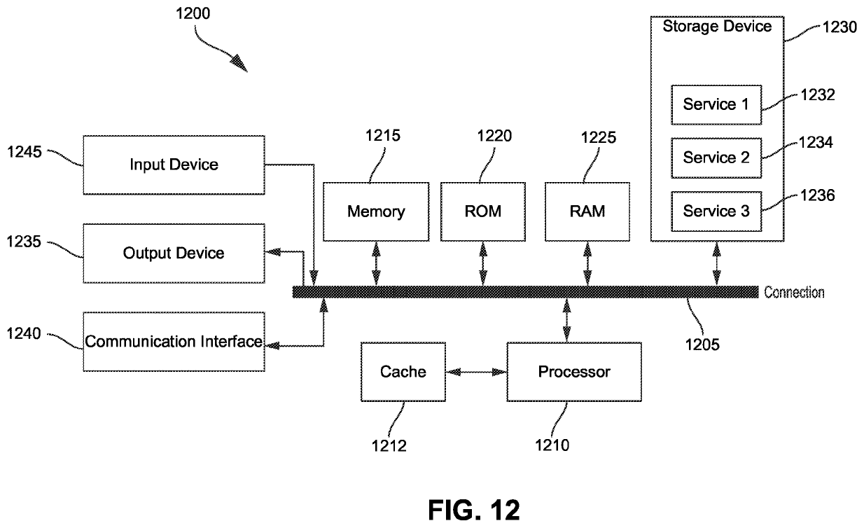

FIG. 12 is a diagram illustrating an example of a system for implementing certain aspects of the present technology. In particular, FIG. 12 illustrates an example of computing system 1200 which can include a piezoelectric MEMS sensor system (e.g., at least one piezoelectric MEMS acoustic sensor or microphone and at least one piezoelectric MEMS transducer system including a piezoelectric MEMS acoustic transducer in a feedback transduction configuration as described above) in accordance with aspects described herein. The acoustic transducer (e.g., the piezoelectric MEMS acoustic transducer and an associated MEMS transducer system.) can be integrated, for example, with any computing device making up internal computing system, a remote computing system, a camera, or any component thereof in which the components of the system are in communication with each other using connection 1205. Connection 1205 may be a physical connection using a bus, or a direct connection into processor 1210, such as in a chipset architecture. Connection 1205 may also be a virtual connection, networked connection, or logical connection.

Example system 1200 includes at least one processing unit (CPU or processor) 1210 and connection 1205 that communicatively couples various system components including system memory 1215, such as read-only memory (ROM) 1220 and random access memory (RAM) 1225 to processor 1210. Computing system 1200 may include a cache 1212 of high-speed memory connected directly with, in close proximity to, or integrated as part of processor 1210.

Processor 1210 may include any general purpose processor and a hardware service or software service, such as services 1232, 1234, and 1236 stored in storage device 1230, configured to control processor 1210 as well as a special-purpose processor where software instructions are incorporated into the actual processor design. Processor 1210 may essentially be a completely self-contained computing system, containing multiple cores or processors, a bus, memory controller, cache, etc. A multi-core processor may be symmetric or asymmetric.

To enable user interaction, computing system 1200 includes an input device 1245, which may represent any number of input mechanisms, such as a microphone for speech or audio detection (e.g., piezoelectric MEMS transducer or a MEMS transducer system in accordance with aspects described above, etc.) along with other input devices 1245 such as a touch-sensitive screen for gesture or graphical input, keyboard, mouse, motion input, speech, etc. Computing system 1200 may also include output device 1235, which may be one or more of a number of output mechanisms. In some instances, multimodal systems may enable a user to provide multiple types of input/output to communicate with computing system 1200.

Computing system 1200 may include communications interface 1240, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 1240 may also include one or more Global Navigation Satellite System (GNSS) receivers or transducers that are used to determine a location of the computing system 1200 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1230 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1) cache, Level 2 (L2) cache, Level 3 (L3) cache, Level 4 (L4) cache, Level 5 (L5) cache, or other (L #) cache), resistive random-access memory (RRAM/ReRAM), phase change memory (PCM), spin transfer torque RAM (STT-RAM), another memory chip or cartridge, and/or a combination thereof.

The storage device 1230 may include software services, servers, services, etc., that when the code that defines such software is executed by the processor 1210, it causes the system to perform a function. In some embodiments, a hardware service that performs a particular function may include the software component stored in a computer-readable medium in connection with the necessary hardware components, such as processor 1210, connection 1205, output device 1235, etc., to carry out the function. The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

A number of implementations have been described. Nevertheless, it will be understood that various modifications may be made without departing from the spirit and scope of the disclosure. Other embodiments are within the scope of the claims.

A second set of illustrative aspects of the disclosure include:

Aspect 1. A system comprising: a motion sensor; a microphone; a machine learning engine; and at least one package containing the motion sensor, the microphone and the machine learning engine, the at least one package having a base to secure the motion sensor and microphone to a surface, the machine learning engine configured to be trained to differentiate different types of contact on the surface.

Aspect 2. The system of Aspect 1 wherein the base has solder pads that connect the package to a printed circuit board that is in a housing, the housing being coupled with the surface.

Aspect 3. An apparatus comprising a motion sensor; a microphone; a machine learning engine; and at least one package containing the motion sensor, the microphone and the machine learning engine, the at least one package having a base to secure the motion sensor and microphone to a surface, trained to differentiate different types of contact on the surface.

Aspect 4. The apparatus of Aspect 3, wherein the base has solder pads that connect the package to a printed circuit board that is in a housing, the housing being coupled with the surface.

Aspect 5. The apparatus of any of Aspects 3 to 4, wherein the motion sensor, microphone and machine learning engine are in a single package.

Aspect 6. The apparatus of any of Aspects 3 to 5, wherein the motion sensor and microphone are in a first package and the machine learning engine is within a second package and electrically coupled with the first package.

Aspect 7. The apparatus of any of Aspects 3 to 6, wherein the motion sensor and microphone are on a first die and the machine learning engine is on a second die, the first and second dies being within the same package.

Aspect 8. The apparatus of any of Aspects 3 to 7, wherein the motion sensor, microphone, and machine learning engine are formed on a single die.

Aspect 9. The apparatus of any of Aspects 3 to 8, wherein the microphone comprises a piezoelectric MEMS microphone.

Aspect 10. The apparatus of any of Aspects 3 to 9, wherein the motion detector comprises an accelerometer or a piezoelectric MEMS microphone with its aperture occluded.

Aspect 11. The apparatus of any of Aspects 3 to 10, wherein the motion sensor has a bandwidth of between 3 Kilohertz and 8 Kilohertz.

Aspect 12. The apparatus of any of Aspects 3 to 11, wherein the motion sensor has a noise floor of between 100 ug/sqrt (Hz) and 0.5 ug/sqrt (Hz) at 1 kHz, 50 ug/sqrt (Hz) to 5 ug/sqrt (Hz) at 1 KHz.

Aspect 13. The apparatus of any of Aspects 3 to 12, wherein the motion sensor has a noise floor of between 100 ug/sqrt (Hz) and 0.05 ug/sqrt (Hz) at device resonance, 5 ug/sqrt (Hz) to 0.05 ug/sqrt (Hz) at resonance.

Aspect 14. The apparatus of any of Aspects 3 to 13, wherein different types of contact comprise no contact, touch, damage, and/or hard touch.

Aspect 15. The apparatus of any of Aspects 3 to 14, wherein a second motion sensor and second microphone within a second set of packages, the second set of packages configured to be coupled with the surface, the system further being configured to determine the location and/or direction of contact on the surface.

Aspect 16. The apparatus of any of Aspects 3 to 15, wherein the surface acts as a touch surface/sensor.

Aspect 17. A system comprising: a first piezoelectric microelectromechanical systems (MEMS) transducer having a first output, wherein the first piezoelectric MEMS transducer is mechanically coupled to a surface of an object, and wherein the first piezoelectric MEMS transducer is configured to generate a first analog signal at the first output when the first analog signal is transduced by the first piezoelectric MEMS transducer from vibrations propagating through the object; a second piezoelectric MEMS transducer having a second output, wherein the second piezoelectric MEMS transducer is configured to generate a second analog signal at the second output when the second analog signal is transduced by the second piezoelectric MEMS transducer from acoustic vibrations at a location of the object; and classification circuitry coupled to the output of first piezoelectric MEMS transducer and the output of the second piezoelectric MEMS transducer, wherein the classification circuitry is configured to process data from the first analog signal and data from the second analog signal, and to categorize combinations of the first analog signal and the second analog signal received during one or more time frames.

Aspect 18. The system of Aspect 17, wherein the first piezoelectric MEMS transducer has a noise floor defining a noise at a given frequency related to a signal output in gravitational units (g), and wherein the noise floor is between 100 millionths of the gravitation unit (ug) per square root of frequency in Hertz (ug/sqrt (Hz)) and 0.5 ug/sqrt (Hz).

Aspect 19. The system of any of Aspects 17 to 18, wherein the first piezoelectric MEMS transducer has a transduction bandwidth to detect the vibrations propagating through the object at frequencies between 1 kilohertz (kHz) and 8 kHz.

Aspect 20. The system of any of Aspects 17 to 19, wherein the data from the first analog signal comprises: frequency data for the vibrations propagating through the object; and magnitude data for the vibrations propagating through the object, where the magnitude data is associated with a severity of a contact with the object.

Aspect 21. The system of any of Aspects 17 to 20, wherein the one or more time frames comprise a plurality of 20 millisecond (ms) frames.

Aspect 22. The system of any of Aspects 17 to 21, further comprising a first sensor package, wherein the first sensor package comprises a substrate base and a lid, wherein the first piezoelectric MEMS transducer, the second piezoelectric MEMS transducer, and an application specific integrated circuit (ASIC) are mounted to the substrate base.

Aspect 23. The system of Aspect 22, wherein the ASIC comprises an analog-to-digital converter (ADC), a digital signal processor (DSP), and a controller; wherein the output of the first piezoelectric MEMS transducer is coupled to an input of the ADC via a wire bond; wherein an output of the ADC is coupled to an input of the controller via the digital signal processor; and wherein an output of the controller is coupled to the classification circuitry.

Aspect 24. The system of any of Aspects 21 to 23 further comprising: a second sensor package comprising a third MEMS transducer and a fourth MEMS transducer; wherein the first sensor package is positioned at a first position on the surface of the object; and wherein the second sensor package is positioned at a second position on the surface of the object at a predetermined distance from the first position.

Aspect 25. The system of Aspect 24, wherein the classification circuitry is further configured to detect a position of an impact on the surface of the object based on a time delay or a magnitude difference between vibrations detected at the first sensor package and vibrations detected at the second sensor package.

Aspect 26. The system of any of Aspects 24 to 25 wherein the classification circuitry is coupled to the output of the first piezoelectric MEMS transducer and the output of the second piezoelectric MEMS transducer via an application specific integrated circuit (ASIC), wherein the ASIC is configured to generate the data from the first analog signal and the second analog signal by: converting the first analog signal into a first plurality of data frames associated with the one or more time frames; converting the second analog signal into a second plurality of data frames associated with the one or more time frames; calculating a sum of a square of amplitude values for each data frame of the first plurality of data frames to generate an amplitude value for the first piezoelectric MEMS transducer for each of the one or more time frames; calculating a sum of a square of amplitude values for each data frame of the second plurality of data frames to generate and an amplitude value for the second piezoelectric MEMS transducer for each of the one or more time frames; and calculating a number of zero crossing for each data frame of the first plurality of data frames to generate a zero crossing value for the first piezoelectric MEMS transducer for each of the one or more time frames; calculating a number of zero crossing for each data frame of the second plurality of data frames to generate a zero crossing value for the second piezoelectric MEMS transducer for each of the one or more time frames; and calculating a ratio value for each of the one or more time frames, wherein the ratio value is a ratio between: the sum of the square of the amplitude for each data frame of the first plurality of data frames; and the sum of the square of the amplitude for each data frame of the second plurality of data frames.

Aspect 27. The system of any of Aspects 17 to 26, wherein the classification circuitry is further configured to receive the data from the first analog signal and the data from the second analog signal as training data in a training mode, and to match the data from the first analog signal and the data from the second analog signal to a provided training classification value.

Aspect 28. The system of any of Aspects 17 to 27, wherein the object is a bumper, and wherein the surface is an externally facing surface of the bumper.

Aspect 29. The system of any of Aspects 27 to 28, wherein the provided training classification value is a collision classification value.

Aspect 30. The system of any of Aspects 17 to 29 further comprising control circuitry coupled to the classification circuitry, wherein the control circuitry is configured to automatically generate an alert in response to receiving a collision classification output from the classification circuitry during an operating mode.

Aspect 31. The system of any of Aspects 27 to 28, wherein the provided training classification value is a door close value, and wherein control circuitry coupled to the classification circuitry is configured to generate a record of a timing of the door close value during an operating mode.

Aspect 32. The system of any of Aspects 27 to 28, wherein the provided training classification value is a key scratch value, and wherein control circuitry coupled to the classification circuitry is configured to initiate a video recording of an area surrounding the surface in response to the key scratch value during an operating mode.

Aspect 33. The system of any of Aspects 17 to 32, wherein the object is an element of a robotic arm, a wall of a storage container, a wall of a building, a hull panel of a ship, or a hull panel of an airplane.

Aspect 34. The system of any of Aspects 17 to 33, wherein the classification circuitry comprises one or more of decision tree circuitry, a support vector machine, or a neural network.

Aspect 35. A method comprising: storing, in a memory of a device, data from a first analog signal generated by a first piezoelectric microelectromechanical systems (MEMS) transducer having a first output, wherein the first piezoelectric MEMS transducer is mechanically coupled to a first surface of an object, and wherein the first piezoelectric MEMS transducer is configured to generate the first analog signal at the first output when the first analog signal is transduced by the first piezoelectric MEMS transducer from vibrations propagating through the object; storing, in the memory of the device, data from a second piezoelectric MEMS transducer having a second output, wherein the second piezoelectric MEMS transducer is configured to generate the second analog signal at the second output when the second analog signal is transduced by the second piezoelectric MEMS transducer from acoustic vibrations incident on the first surface of the object; and processing, using classification circuitry coupled to the output of first piezoelectric MEMS transducer and the output second piezoelectric MEMS transducer, the data from the first analog signal and the data from the second analog signal to categorize combinations of the first analog signal and the second analog signal received during one or more time frames.

Aspect 36. The method of Aspect 35, further comprising: processing the first analog signal and the second analog signal using a digital signal processor (DSP) and an analog to digital converter (ADC) to generate the data from the first analog signal and the data from the second analog signal as digital data.

Aspect 37. A system comprising: means for generating a first analog signal transduced from vibrations propagating through an object having a first surface; means for generating a second analog signal transduced from acoustic signals incident on the first surface of the object; and means for processing data from the first analog signal and data from the second analog signal to classify combinations of the first analog signal and the second analog signal received during one or more time frames.

Aspect 38. The system of Aspect 37, wherein the means for generating the first analog signal has a noise floor defining a noise at a given frequency related to a signal output in gravitational units (g), and wherein the noise floor is between 100 millionths of the gravitation unit (ug) per square root of frequency in Hertz (ug/sqrt (Hz)) and 0.5 ug/sqrt (Hz).

Aspect 39. A system comprising: a motion sensor; a microphone; a machine learning engine; and at least one package containing the motion sensor, the microphone and the machine learning engine, the at least one package having a base to secure the motion sensor and microphone to a surface, the machine learning engine configured to be trained to differentiate different types of contact on the surface.

Aspect 40. The system of Aspect 39, wherein the base has solder pads that connect the at least one package to a printed circuit board that is in a housing, the housing being coupled with the surface.

Aspect 41. The system of any of Aspects 39 to 40, wherein the motion sensor, the microphone and the machine learning engine are in a single package.

Aspect 42. The system of any of Aspects 39 to 40, wherein the motion sensor and the microphone are on a first die and the machine learning engine is on a second die, the first and second dies being within the single package.

Aspect 43. The system of any of Aspects 39 to 40, wherein the motion sensor and the microphone are in a first package and the machine learning engine is within a second package and electrically coupled with the first package.

Aspect 44. The system of any of Aspects 39 to 41, wherein the motion sensor, the microphone, and the machine learning engine are formed on a single die.

Aspect 45. The system of any of Aspects 39 to 44, wherein the microphone comprises a piezoelectric MEMS microphone.

Aspect 46. The system of any of Aspects 39 to 45, wherein the motion sensor comprises an accelerometer or a piezoelectric MEMS microphone with an occluded aperture.

Aspect 47. A microelectromechanical (MEMS) transducer, comprising means for providing an output signal in accordance with any aspect above.

Aspect 48. A method for operating any MEMS transducer described herein.

Aspect 49. A storage medium comprising instructions that, when executed by one or more processors of a system, causes the system to perform any operations described herein.

What is claimed is:

1. A system comprising:
a first piezoelectric microelectromechanical systems (MEMS) transducer having a first output, wherein the first piezoelectric MEMS transducer is mechanically coupled to a surface of an object, and wherein the first piezoelectric MEMS transducer is configured to generate a first analog signal at the first output when the first analog signal is transduced by the first piezoelectric MEMS transducer from vibrations propagating through the object;
a second piezoelectric MEMS transducer having a second output, wherein the second piezoelectric MEMS transducer is configured to generate a second analog signal at the second output when the second analog signal is transduced by the second piezoelectric MEMS transducer from acoustic vibrations at a location of the object; and
classification circuitry coupled to the output of first piezoelectric MEMS transducer and the output of the second piezoelectric MEMS transducer, wherein the classification circuitry is configured to process data from the first analog signal and data from the second analog signal, and to categorize combinations of the first analog signal and the second analog signal received during one or more time frames.

2. The system of claim 1, wherein the first piezoelectric MEMS transducer has a noise floor defining a noise at a given frequency related to a signal output in gravitational units (g), and wherein the noise floor is between 100 millionths of the gravitation unit (ug) per square root of frequency in Hertz (ug/sqrt (Hz)) and 0.5 ug/sqrt (Hz).

3. The system of claim 1, wherein the first piezoelectric MEMS transducer has a transduction bandwidth to detect the vibrations propagating through the object at frequencies between 1 kilohertz (kHz) and 8 kHz.

4. The system of claim 1, wherein the data from the first analog signal comprises:
frequency data for the vibrations propagating through the object; and
magnitude data for the vibrations propagating through the object, where the magnitude data is associated with a severity of a contact with the object.

5. The system of claim 1, wherein the one or more time frames comprise a plurality of 20 millisecond (ms) frames.

6. The system of claim 1, further comprising a first sensor package, wherein the first sensor package comprises a substrate base and a lid, wherein the first piezoelectric MEMS transducer, the second piezoelectric MEMS transducer, and an application specific integrated circuit (ASIC) are mounted to the substrate base.

7. The system of claim 6, wherein the ASIC comprises an analog-to-digital converter (ADC), a digital signal processor (DSP), and a controller;
wherein the output of the first piezoelectric MEMS transducer is coupled to an input of the ADC via a wire bond;
wherein an output of the ADC is coupled to an input of the controller via the digital signal processor; and
wherein an output of the controller is coupled to the classification circuitry.

8. The system of claim 6 further comprising:
a second sensor package comprising a third MEMS transducer and a fourth MEMS transducer;
wherein the first sensor package is positioned at a first position on the surface of the object; and
wherein the second sensor package is positioned at a second position on the surface of the object at a predetermined distance from the first position.

9. The system of claim 8, wherein the classification circuitry is further configured to detect a position of an impact on the surface of the object based on a time delay or a magnitude difference between vibrations detected at the first sensor package and vibrations detected at the second sensor package.

10. The system of claim 1, wherein the classification circuitry is coupled to the output of the first piezoelectric MEMS transducer and the output of the second piezoelectric MEMS transducer via an application specific integrated circuit (ASIC), wherein the ASIC is configured to generate the data from the first analog signal and the second analog signal by:
converting the first analog signal into a first plurality of data frames associated with the one or more time frames;
converting the second analog signal into a second plurality of data frames associated with the one or more time frames;
calculating a sum of a square of amplitude values for each data frame of the first plurality of data frames to generate an amplitude value for the first piezoelectric MEMS transducer for each of the one or more time frames;
calculating a sum of a square of amplitude values for each data frame of the second plurality of data frames to generate and an amplitude value for the second piezoelectric MEMS transducer for each of the one or more time frames; and
calculating a number of zero crossing for each data frame of the first plurality of data frames to generate a zero crossing value for the first piezoelectric MEMS transducer for each of the one or more time frames;
calculating a number of zero crossing for each data frame of the second plurality of data frames to generate a zero crossing value for the second piezoelectric MEMS transducer for each of the one or more time frames; and
calculating a ratio value for each of the one or more time frames, wherein the ratio value is a ratio between:
the sum of the square of the amplitude for each data frame of the first plurality of data frames; and
the sum of the square of the amplitude for each data frame of the second plurality of data frames.

11. The system of claim 10, wherein the classification circuitry is further configured to receive the data from the first analog signal and the data from the second analog signal as training data in a training mode, and to match the data from the first analog signal and the data from the second analog signal to a provided training classification value.

12. The system of claim 11, wherein the object is a bumper, and wherein the surface is an externally facing surface of the bumper.

13. The system of claim 12, wherein the provided training classification value is a collision classification value.

14. The system of claim 13 further comprising control circuitry coupled to the classification circuitry, wherein the control circuitry is configured to automatically generate an alert in response to receiving a collision classification output from the classification circuitry during an operating mode.

15. The system of claim 12, wherein the provided training classification value is a door close value, and wherein control circuitry coupled to the classification circuitry is configured to generate a record of a timing of the door close value during an operating mode.

16. The system of claim 12, wherein the provided training classification value is a key scratch value, and wherein control circuitry coupled to the classification circuitry is configured to initiate a video recording of an area surrounding the surface in response to the key scratch value during an operating mode.

17. The system of claim 1, wherein the object is an element of a robotic arm, a wall of a storage container, a wall of a building, a hull panel of a ship, or a hull panel of an airplane.

18. The system of claim 1, wherein the classification circuitry comprises one or more of decision tree circuitry, a support vector machine, or a neural network.

19. A method comprising:
storing, in a memory of a device, data from a first analog signal generated by a first piezoelectric microelectromechanical systems (MEMS) transducer having a first output, wherein the first piezoelectric MEMS transducer is mechanically coupled to a first surface of an object, and wherein the first piezoelectric MEMS transducer is configured to generate the first analog signal at the first output when the first analog signal is transduced by the first piezoelectric MEMS transducer from vibrations propagating through the object;
storing, in the memory of the device, data from a second piezoelectric MEMS transducer having a second output, wherein the second piezoelectric MEMS transducer is configured to generate the second analog signal at the second output when the second analog signal is transduced by the second piezoelectric MEMS transducer from acoustic vibrations incident on the first surface of the object; and
processing, using classification circuitry coupled to the output of first piezoelectric MEMS transducer and the output second piezoelectric MEMS transducer, the data from the first analog signal and the data from the second analog signal to categorize combinations of the first analog signal and the second analog signal received during one or more time frames.

20. The method of claim 19, further comprising:
processing the first analog signal and the second analog signal using a digital signal processor (DSP) and an analog to digital converter (ADC) to generate the data from the first analog signal and the data from the second analog signal as digital data.

21. A system comprising:
means for generating a first analog signal transduced from vibrations propagating through an object having a first surface;
means for generating a second analog signal transduced from acoustic signals incident on the first surface of the object; and
means for processing data from the first analog signal and data from the second analog signal to classify combinations of the first analog signal and the second analog signal received during one or more time frames.

22. The system of claim 21, wherein the means for generating the first analog signal has a noise floor defining a noise at a given frequency related to a signal output in gravitational units (g), and wherein the noise floor is between 100 millionths of the gravitation unit (ug) per square root of frequency in Hertz (ug/sqrt (Hz)) and 0.5 ug/sqrt (Hz).

23. A system comprising:
a motion sensor;
a microphone;
a machine learning engine; and
at least one package containing the motion sensor, the microphone and the machine learning engine, the at least one package having a base to secure the motion sensor and microphone to a surface, the machine learning engine configured to be trained to differentiate different types of contact on the surface.

24. The system of claim 23, wherein the base has solder pads that connect the at least one package to a printed circuit board that is in a housing, the housing being coupled with the surface.

25. The system of claim 23, wherein the motion sensor, the microphone and the machine learning engine are in a single package.

26. The system of claim 23, wherein the motion sensor and the microphone are in a first package and the machine learning engine is within a second package and electrically coupled with the first package.

27. The system of claim 25, wherein the motion sensor and the microphone are on a first die and the machine learning engine is on a second die, the first and second dies being within the single package.

28. The system of claim 23, wherein the motion sensor, the microphone, and the machine learning engine are formed on a single die.

29. The system of claim 28, wherein the microphone comprises a piezoelectric MEMS microphone.

30. The system of claim 23, wherein the motion sensor comprises an accelerometer or a piezoelectric MEMS microphone with an occluded aperture.
